(19) United States
(12) Patent Application Publication
(10) Pub. No.: US 2020/0395453 A1
(43) Pub. Date: Dec. 17, 2020

(54) NANOGAP ELECTRODE AND METHOD OF MAKING THE SAME, AND NANO-DEVICE HAVING A NANOGAP ELECTRODE

(71) Applicant: JAPAN SCIENCE AND TECHNOLOGY AGENCY, Kawaguchi-shi (JP)

(72) Inventors: Yutaka MAJIMA, Yokohama-shi (JP); YoonYoung CHOI, Yokohama-shi (JP); Ain KWON, Yokohama-shi (JP)

(21) Appl. No.: 17/006,437

(22) Filed: Aug. 28, 2020

Related U.S. Application Data
(63) Continuation of application No. PCT/JP2019/007937, filed on Feb. 28, 2019.

(30) Foreign Application Priority Data
Mar. 2, 2018 (JP) 2018-038092

(51) Int. Cl. H01L 29/41; H01L 29/40; H01L 29/76; B82Y 10/00

(52) U.S. Cl. CPC H01L 29/413; B82Y 10/00; H01L 29/7613; H01L 29/401

(57) ABSTRACT

A nanogap electrode in an embodiment according to the present invention includes a first electrode including a first electrode layer and a first metal particle arranged at one end of the first electrode layer, and a second electrode including a second electrode layer and a second metal particle arranged at one end of the second electrode layer. The first metal particle and the second metal particle are arranged opposite to each other with a gap therebetween, and a width from one end to the other end of the first metal particle and the second metal particle is 20 nm or less. The gap between the first metal particle and the second metal particle is 10 nm or less.

### CROSS REFERENCE TO RELATED APPLICATIONS

This application is based upon and claims the benefit of priority from the prior Japanese Patent Application No. 2018-038092, filed on Mar. 2, 2018, and PCT Application No. PCT/JP2019/007937 filed on Feb. 28, 2019, the entire contents of which are incorporated herein by reference.

### FIELD

One embodiment of the present invention relates to electrodes having nanoscale gap length and methods of manufacturing the same, and nano devices having nanogap electrodes.

### BACKGROUND

Semiconductor integrated circuit has increased the degree of integration exponentially according to Moore's law. However, it is said that the miniaturization technique for semi-conductor integrated circuit is gradually approaching its limits. Faced with the limitations of such technological advances, research has been underway to realize new electronic devices by using bottom-up techniques for constructing devices from molecules in which atoms or structures, which are the smallest units of materials, are defined, rather than top-down techniques for processing and miniaturizing materials. For example, research is underway on nanogap electrodes that utilize the self-terminating function of electroless plating, and nano-devices that place metal nanoparticles between nanogap electrodes.

### SUMMARY

A nanogap electrode in an embodiment according to the present invention includes a first electrode including a first electrode layer and a first metal particle arranged at one end of the first electrode layer, and a second electrode including a second electrode layer and a second metal particle arranged at one end of the second electrode layer. The first metal particle and the second metal particle are arranged opposite to each other with a gap therebetween, and a width from one end to the other end of the first metal particle and the second metal particle is 20 nm or less. The gap between the first metal particle and the second metal particle is 10 nm or less.

A method for manufacturing nanogap electrode in an embodiment according to the present invention, the method includes forming a first electrode layer and a second electrode layer on a substrate having an insulating surface so that one ends of the first electrode layer and the second electrode layer are opposed to each other with a gap therebetween, dipping the substrate on which the first electrode layer and the second electrode layer are formed in an electroless plating solution in which a reducing agent is mixed into an electrolyte containing metal ions, forming metal particles one end of each of the first electrode layer and the second electrode layer, and forming a metallic bond between a metal forming the first electrode layer and the second electrode layer and a metal contained in the electroless plating solution, growing the metal particles to a size in which the width from one end to the other end of the metal particles is not more than 10 nm, and forming a gap of 10 nm or less between the metal particles formed at the one end of the first electrode layer and the one end of the second electrode layer.

A nanodevice in an embodiment according to the present invention includes a first electrode including a first electrode layer and a first metal particle arranged at one end of the first electrode layer, a second electrode including a second electrode layer and a second metal particle arranged at one end of the second electrode layer, and a metal nanoparticle or a functional molecule. The first metal particle and the second metal particle are arranged opposite to each other with a gap therebetween, the metal nanoparticle or the functional molecule are arranged in the gap between the first metal particle and the second metal particle, and a width from one end to the other end of the first metal particle and the second metal particle is 10 nm or less. The gap between the first metal particle and the second metal particle is 10 nm or less.

### BRIEF DESCRIPTION OF DRAWINGS

FIG. 1A shows a plan view of nanogap electrodes according to an embodiment;

FIG. 1B shows a partially enlarged view of a nanogap electrode according to an embodiment of the present invention;

FIG. 10 shows a cross-sectional view of nanogap electrodes according to an embodiment;

FIG. 2A shows a plan view of nanogap electrodes according to an embodiment;

FIG. 2B shows a cross-sectional view of nanogap electrodes according to an embodiment;

FIG. 3A shows the configuration of the gap of a nanogap electrode, wherein tip portion of the electrode is rounded and chamfered according to an embodiment of the present invention;

FIG. 3B is a configuration of a gap portion of a nanogap electrode according to an embodiment of the present invention, wherein tip portion of the electrode is shaped to an acute angle;

FIG. 4A is a schematic diagram of a nanogap electrode according to an embodiment of the present invention, wherein electrode layers are formed;

FIG. 4B is a schematic diagram of a nanogap electrode according to an embodiment of the present invention, wherein metal particles are disposed on the surfaces of the electrode layers;

FIG. 5A is a cross-sectional view illustrating a process for fabricating a nanogap electrode according to an embodiment of the present invention, wherein a metallic layer is formed;

FIG. 5B is a cross-sectional view illustrating a process for fabricating a nanogap electrode according to an embodiment of the present invention, and shows a step of forming electrode layers;

FIG. 5C is a cross-sectional view illustrating a process for making a nanogap electrode according to an embodiment of the present invention, wherein the nanogap electrode is arranged in metal particles;

FIG. 6A shows plan view of a nano-device with nanogap electrodes according to an embodiment of the present invention;

FIG. 6B shows cross-sectional view of a nano-device with nanogap electrodes according to an embodiment of the present invention;

FIG. 7A shows a plan view of a nano-device with nanogap electrodes according to an embodiment of the present invention;

FIG. 7B shows cross-sectional view of a nano-device with nanogap electrodes according to an embodiment of the present invention;

FIG. 8A shows a plan view of a nano-device with nanogap electrodes according to an embodiment of the present invention;

FIG. 8B shows cross-sectional view of a nano-device with nanogap electrodes according to an embodiment of the present invention;

FIG. 9A shows a plan view of a nano-device with nanogap electrodes according to an embodiment of the present invention;

FIG. 9B shows cross-sectional view of a nano-device with nanogap electrodes according to an embodiment of the present invention;

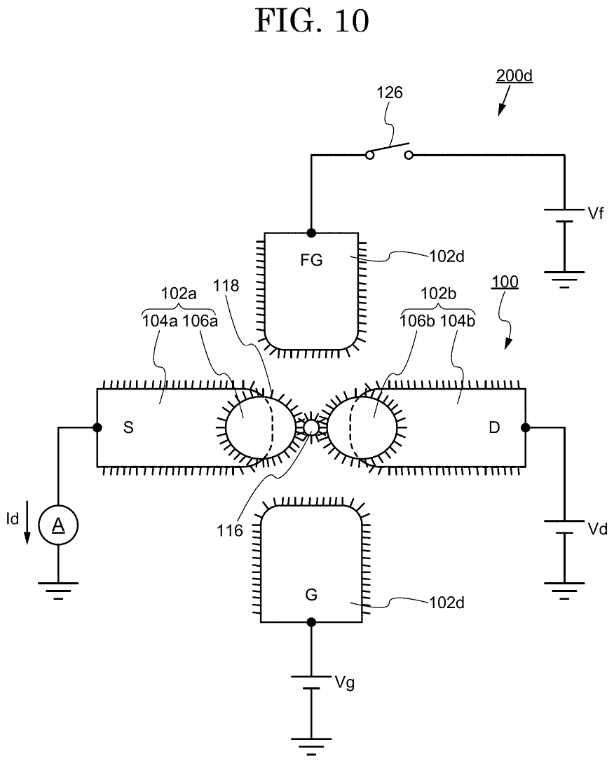

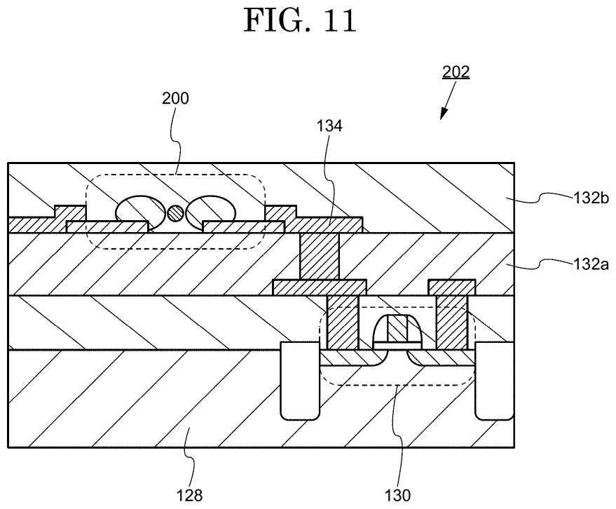

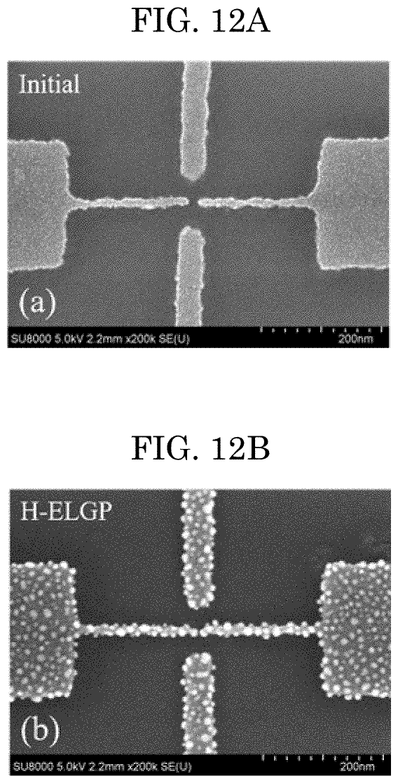

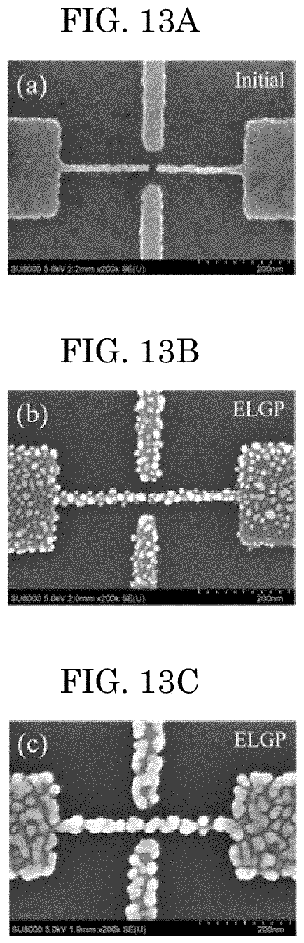

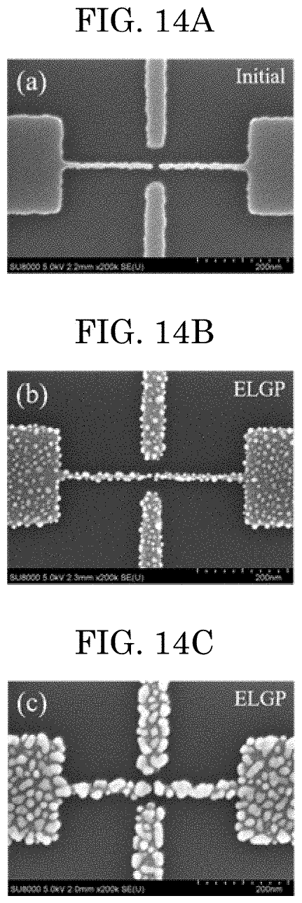

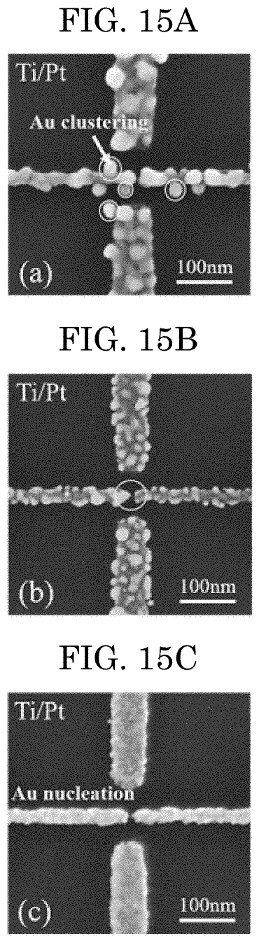

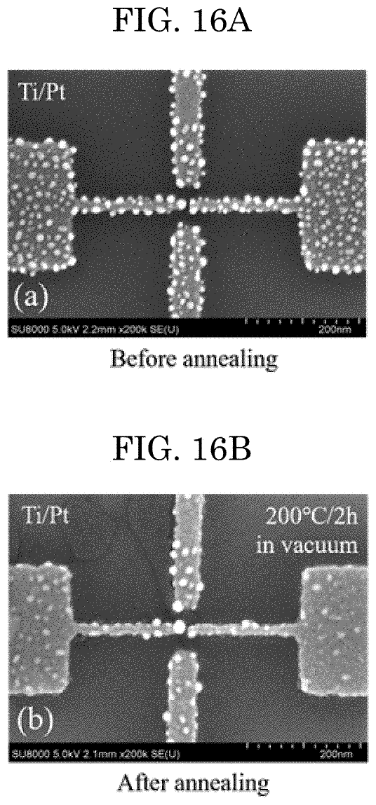

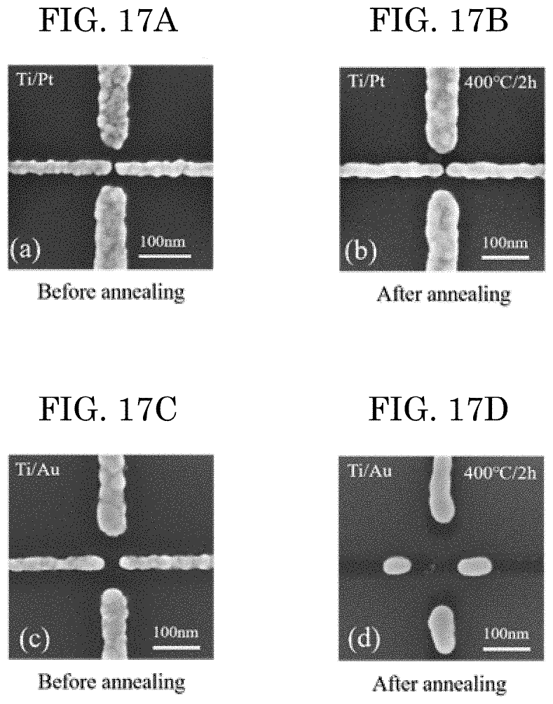

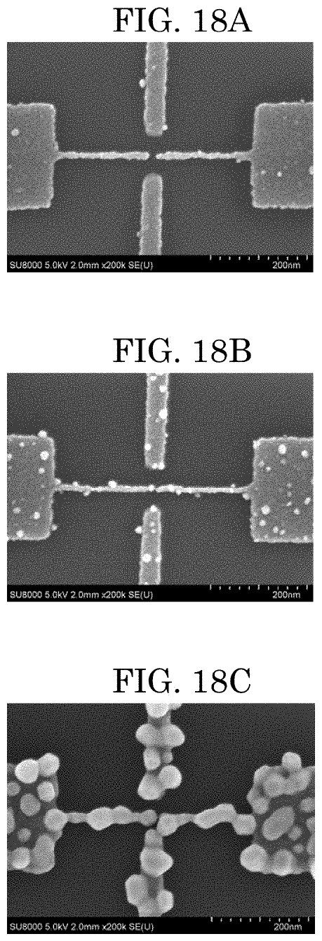

FIG. 10 shows a plan view of a nano-device with nanogap electrodes according to an embodiment of the present invention;

FIG. 11 shows a cross-sectional view of integrated circuit provided with a nano-device having nanogap electrodes according to an embodiment of the present invention;

FIG. 12A shows an SEM image of a nanogap electrode before gold particles are formed in the example 1;

FIG. 12B shows an SEM image of a nanogap electrode with gold particles formed in the example 1;

FIG. 13A shows an SEM image of the nanogap electrode prior to electroless plating in the example 2;

FIG. 13B shows an SEM image of a nanogap electrode treated with the electroless plating solution of condition 1 in the example 2;

FIG. 13C shows an SEM image of a nanogap electrode treated with an electroless plating solution of condition 2 in the example 2;

FIG. 14A shows an SEM image of the nanogap electrode prior to electroless plating in the example 2;

FIG. 14B shows an SEM image of a nanogap electrode processed for 10 seconds with the electroless plating solution of condition 1 in the example 2;

FIG. 14C shows an SEM image of a nanogap electrode treated with the electroless plating solution of condition 1 for 20 seconds in the example 2;

FIG. 15A shows an SEM image of a nanogap electrode fabricated without pretreatment in the example 3;

FIG. 15B shows an SEM image of a nanogap electrode prepared by pretreatment with solution A in example 3;

FIG. 15C shows an SEM image of a nanogap electrode prepared by pretreatment with solution B in example 3;

FIG. 16A shows an SEM image prior to heat treatment of a sample evaluated for the heat resistance of the nanogap electrode fabricated in the example 4;

FIG. 16B shows an SEM image after heat treatment of the sample evaluated the heat resistance of the nanogap electrode prepared in the example 4;

FIG. 17A shows the result of evaluating the heat resistance of the sample of the reference example, and shows an SEM image of the sample 1 (titanium (Ti)/platinum (Pt) nanogap electrode) before heat treatment;

FIG. 17B shows the result of evaluating the heat resistance of the sample of the reference example, and shows an SEM image after heat treatment of the sample 1 (titanium (Ti)/platinum (Pt) nanogap electrode);

FIG. 17C shows the results of evaluating the heat resistance of the sample of the reference example, showing an SEM image before the heat treatment of the sample 2 (titanium (Ti)/gold (Au) nanogap electrode);

FIG. 17D shows the results of evaluating the heat resistance of the sample of the reference example, showing an SEM image after heat treatment of the sample 2 (titanium (Ti)/gold (Au) nanogap electrode);

FIG. 18A shows an SEM image of a sample prepared in the example 5 and subjected to molecular ruler electroless plating for 3 minutes;

FIG. 18B shows an SEM image of a sample of the nanogap electrode produced in the example 5, which was subjected to molecular ruler electroless gold plating for 6 minutes; and

FIG. 18C shows an SEM image of a sample obtained by performing molecular ruler electroless gold plating on a nanogap electrode produced in the example 5 for 10 minutes.

### DESCRIPTION OF EMBODIMENTS

Embodiments of the present invention will be described below with reference to the drawings and the like. However, the present invention may be practiced in many ways and is not to be construed as being limited to the description of the embodiments illustrated below. In order to make the explanation clearer, the drawing may schematically show the width, thickness, shape, etc. of each part in comparison with the actual embodiment. However, it is an example and is not intended to limit the interpretation of the present invention. In this specification and each figure, elements similar to those described above with respect to the previously described figures are denoted by the same reference numerals (or a number followed by a, b, etc.) and detailed description thereof may be omitted as appropriate. In addition, the letters “First” and “Second” appended to each element are expedient signs used to distinguish between the elements and have no further meaning unless otherwise stated.

In the present specification, the nanogap electrode has a gap portion (gap) between a pair of electrodes, and the length of the gap portion (gap length) is 10 nm or less, for example, 1 nm to 10 nm, unless otherwise specified.

In the present specification, a nano-device refers to a device including a configuration of a nanogap electrode.

### First Embodiment

A structure and a manufacturing method of a nanogap electrode according to an embodiment of the present invention will be described with reference to the drawings.

1-1 Structure of the Nanogap Electrode

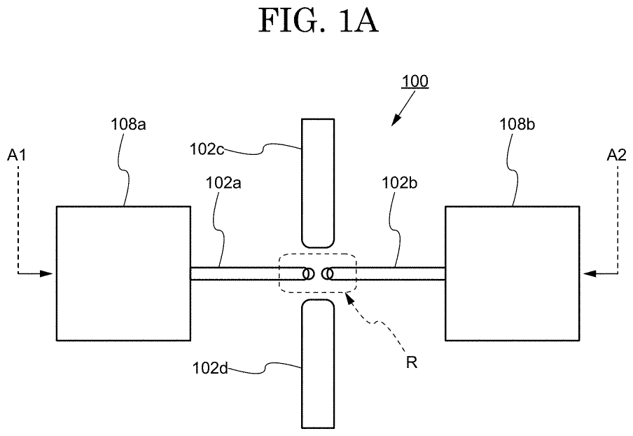

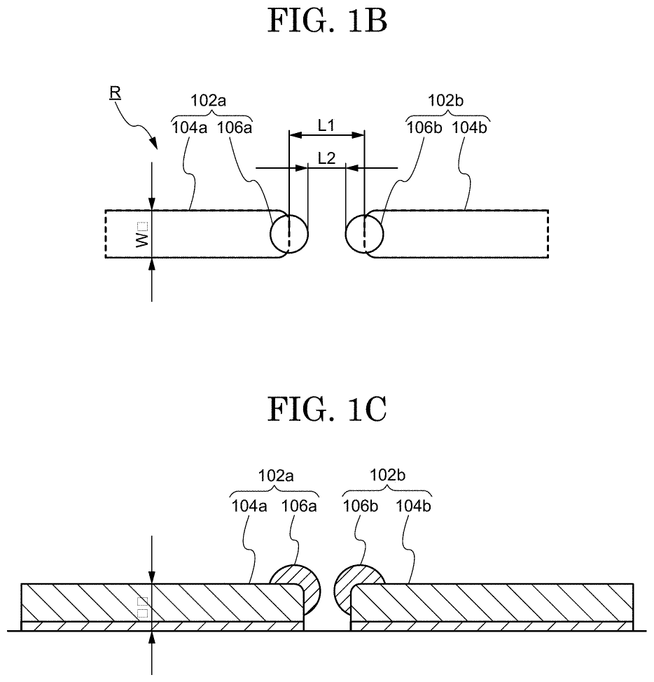

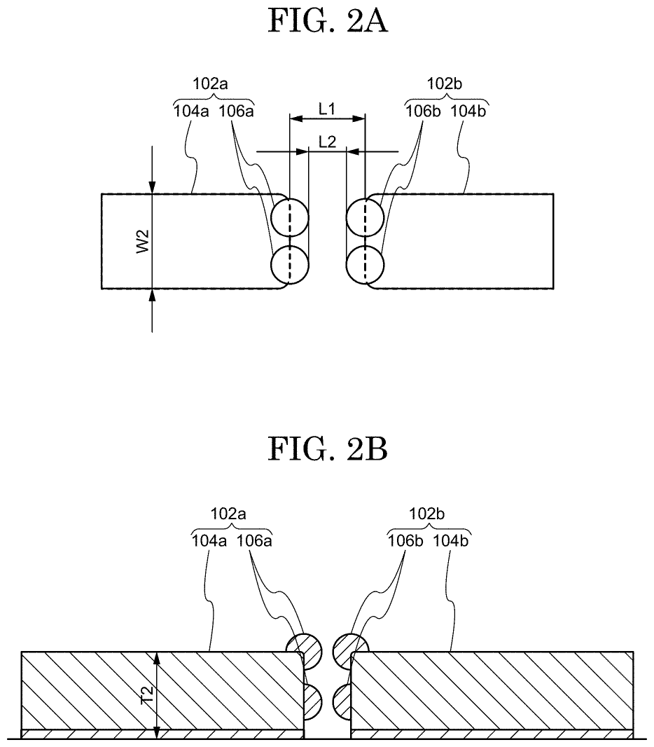

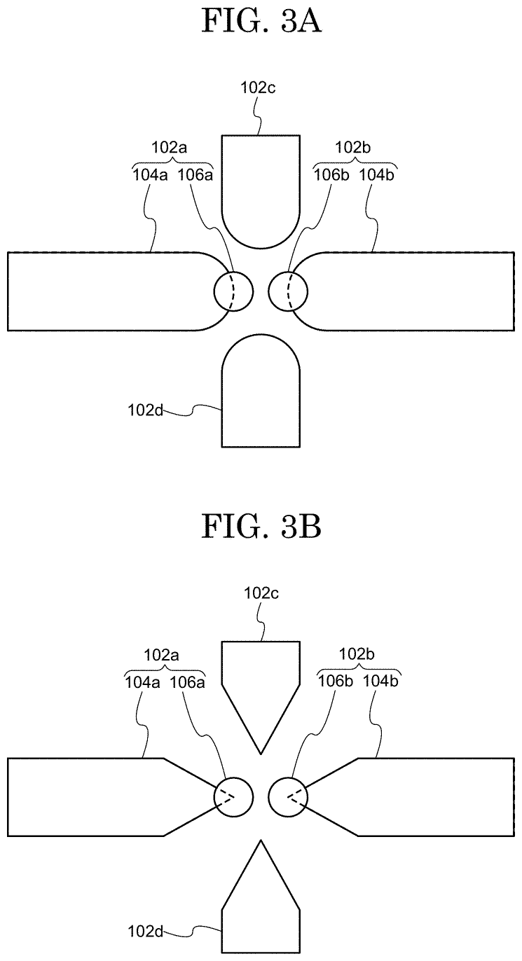

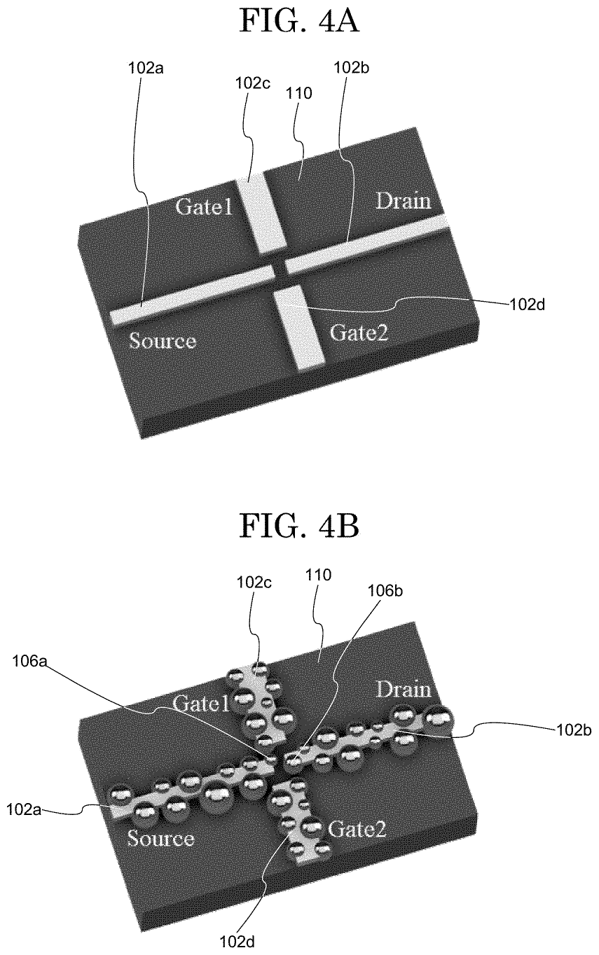

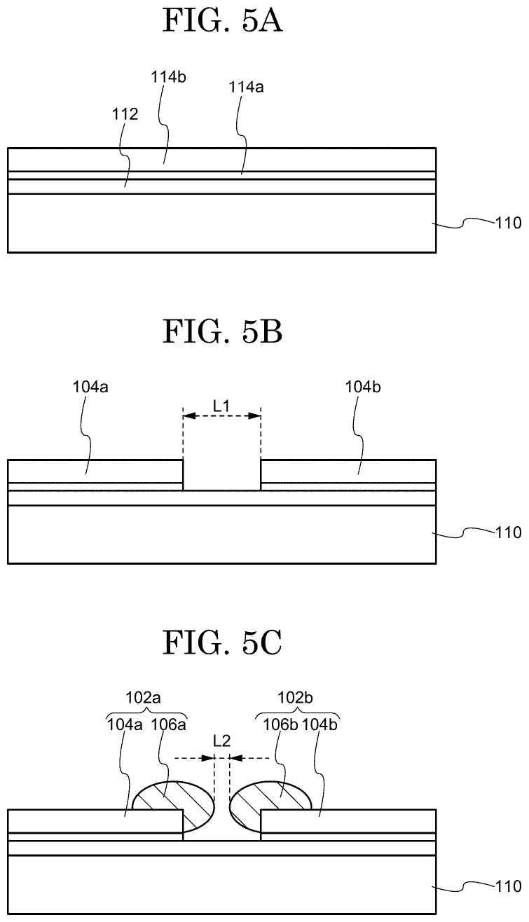

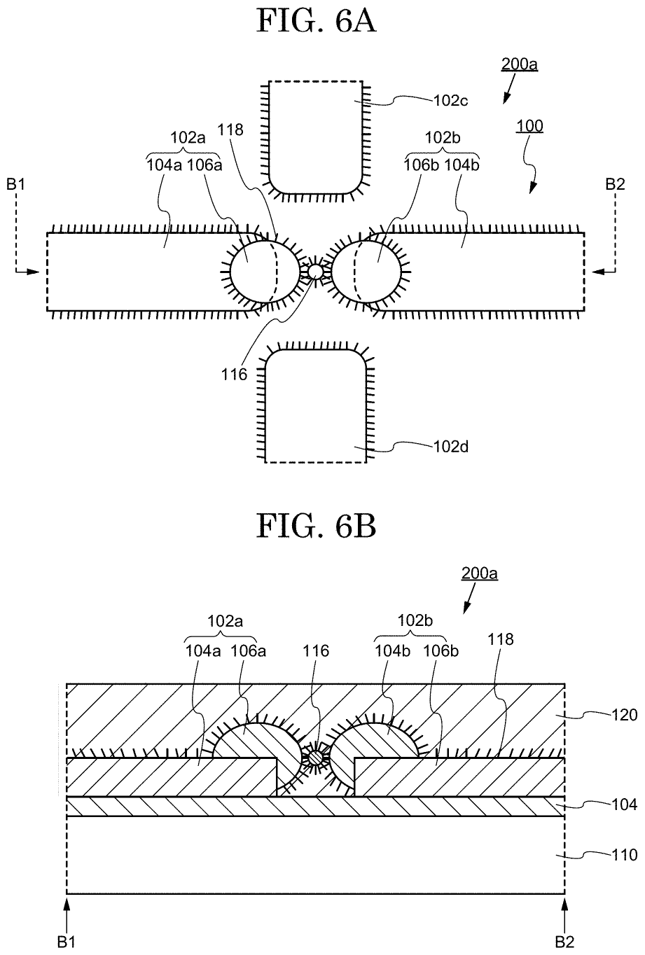

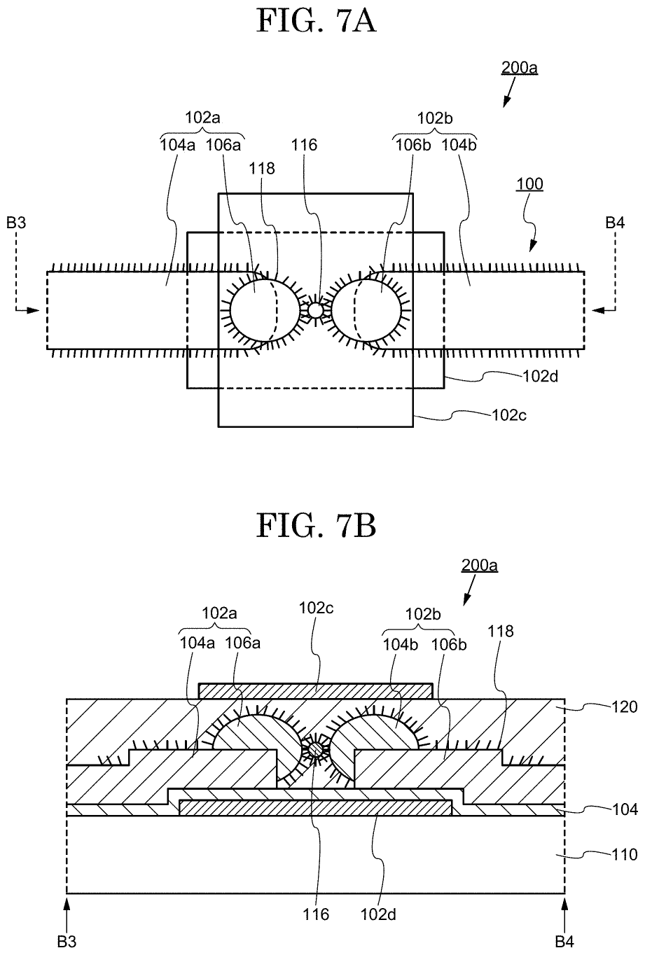

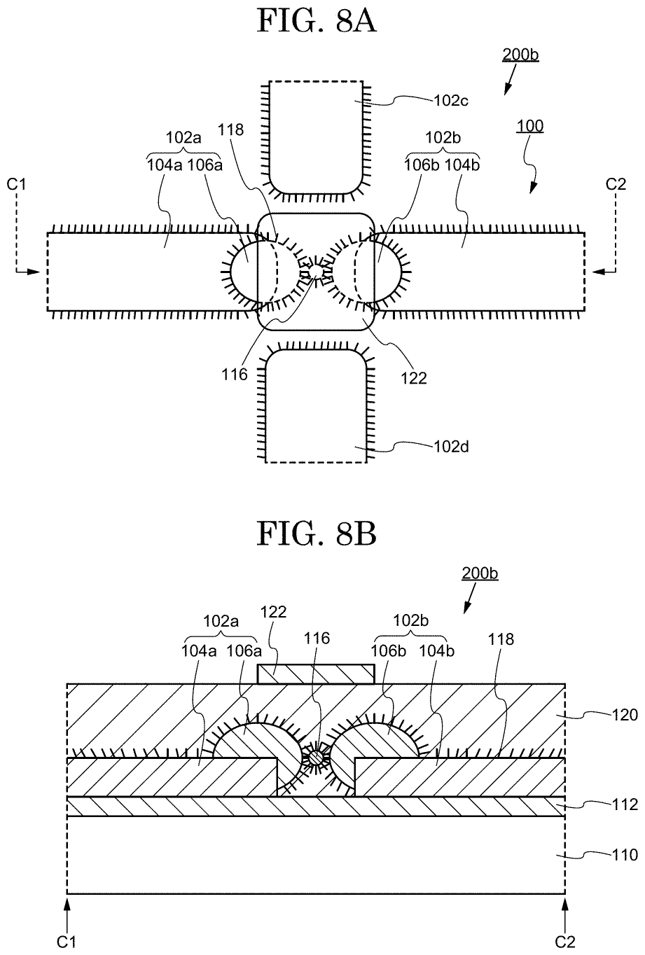

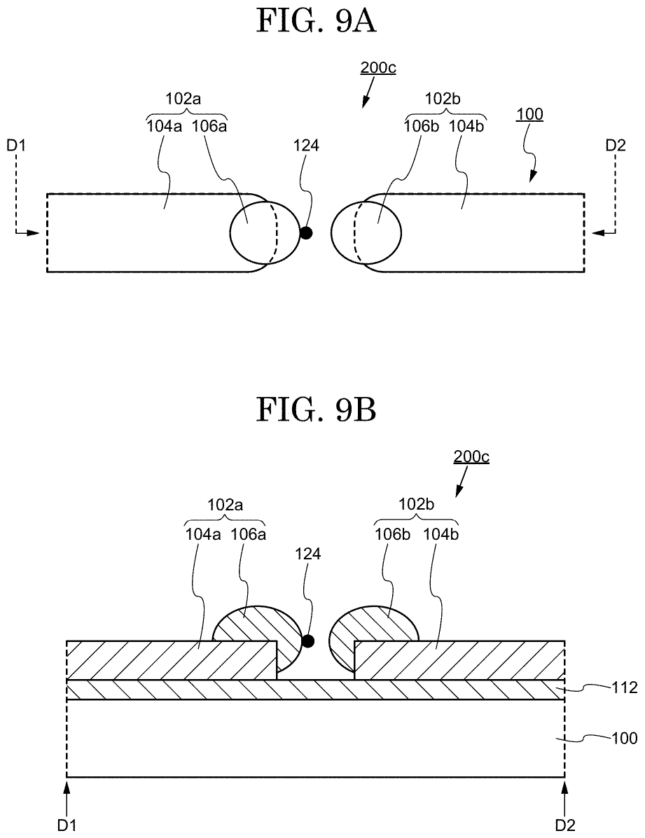

FIG. 1A shows plan view of a nanogap electrode 100 according to the present embodiment, FIG. 1B shows an enlarged view of region R surrounded by a dotted line, FIG. 10 shows a cross-sectional structure corresponding between A1-A2. For the structure of the nanogap electrode 100, these figures shall be referred to in the following description.

In the nanogap electrode 100, one end portions of a first electrode 102a and a second electrode 102b facing each other and are arranged with a gap therebetween. FIG. 1A shows the first electrode 102a and the second electrode 102b in a rectangular configuration, with one end of each longitudinal orientation opposed and arranged with nanoscale gaps. FIG. 1B shows a detailed view of the gap of the nanogap electrode 100. The first electrode 102a includes a first electrode layer 104a and first metal particle 106a, and a second electrode 102b includes a second electrode layer 104b and a second metal particle 106b. The first metal particle 106a and the second metal particles 106b are preferably formed by, for example, electroless plating, and are provided in close contact with the surfaces of the first electrode layer 104a and the second electrode layer 106b, respectively. The first metal particle 106a are electrically connected to the first electrode layer 104a, and the second metal particles 106b are electrically connected to the second electrode layer 104b. The electrode layers are formed by patterning a conductive thin film such as a metallic film to function as an electrode.

In the FIG. 1B, a spacing of the first electrode layer 104a and the second electrode layer 104b is denoted by L1, and the spacing of the first metal particle 106a and the second metal particle 106b is denoted by L2. In other words, L1 represents the length of the gap in the initial state of the nanogap electrode before the metal particles are disposed (gap length), and L2 represents the length of the actual gap of the nanogap electrode after the metal particles are disposed (gap length). In the nanogap electrode 100, a gap length L2 formed between the first metal particle 106a and the second metal particle 106b is preferably 10 nm or less.

The gap length L2 of the nanogap electrode 100 is not more than 10 nm, but in applications to nano-devices, it is appropriately adjusted depending on the application. For example, when constructing a nano-device tunnel current flows using the nanogap electrode 100, it is preferred that the length of the gap (gap length) L2 to 10 nm or less, when applied to a nano-device that expresses Coulomb blockade, it is preferred that the length of the gap (gap length) L2 to 5 nm or less.

The length of the gap of the nanogap electrode 100, that is, the distance at which the first metal particle 106a and the second metal particle 106b are separated from each other, is controlled by the arrangement of the first electrode layer 104a and a second metal layer 114b. In this sense, the spacing L1 of end portion (tip portion) of each of the first electrode layer 104a and the second electrode layer 104b is preferably arranged at a spacing of 20 nm or less, preferably 15 nm or less.

The length of the gap of the nanogap electrode 100 can be controlled by the position at which the first metal particle 106a and the second metal particle 106b are disposed. The first metal particle 106a and the second metal particle 106b are formed by an electroless plating method. At this time, by setting the widths W1 of the first electrode layer 104a and the second electrode layer 104b to 20 nm or less, preferably 15 nm or less, metal particles can be grown preferentially each of the end portion.

The thickness T1 of the first electrode layer 104a and the second electrode layer 104b may be set as appropriate, but may be set to 20 nm or less, preferably 15 nm or less. Thus, the number of metal particles disposed at one end portion of the first electrode layer 104a and the second electrode layer 104b can be controlled. When gate electrode is disposed on the lower layer side and the upper layer side of the nanogap electrode 100, the thickness T1 of the first electrode layer 104a and the second electrode layer 104b is set to 20 nm or less, preferably 15 nm or less, whereby an electric field generated by the gate voltage can be reliably applied to the gap portion.

Even if the gap length of the nanogap electrode 100 is about 10 nm, if the widths of the first electrode layer 104a and the second electrode layer 104b are wide, operation characteristics of the nano-device are affected. For example, in a single-electron transistor having a nanogap electrode, single-electron islands disposed in the gap portion is electrically shielded by a wide electrode layer, a problem that is less susceptible to the action of the electric field caused by the gate voltage can occur.

However, by setting the thicknesses and widths of the first electrode layer 104a and the second electrode layer 104b within the ranges of the present embodiment, the electric field generated by the gate voltage can be reliably applied to the gap portion in the nano-device including the nanogap electrode 100 and gate electrode. In addition, the number of metal particles disposed at one end portion of the first electrode layer 104a and the second electrode layer 104b can also be controlled.

The gap length of the nanogap electrode 100 can be further controlled by the sizes of the first metal particle 106a and the second metal particle 106b. By forming the first metal particle 106a and the second metal particle 106b to be large, the length (gap length) of the gap can be reduced, and by forming them to be small, the length (gap length) of the gap can be increased. As will be described later, the first metal particle 106a and the second metal particle 106b exhibit a self-terminating function in electroless plating, thereby preventing contact with each other and enabling control of the gap length.

The first metal particle 106a and the second metal particle 106b are provided as a single mass (or island-shaped region) on the respective surfaces of the first electrode layer 104a and the second electrode layer 104b. The first metal particle 106a and the second metal particle 106b have a hemispherical external view like a water droplet dripped on a hydrophobic surface. Here, the hemispherical shape refers to a spherical surface in which curved surface continues and is not limited to a true spherical surface. In the nanogap electrode 100, it is preferable that the first metal particle 106a and the second metal particle 106b do not increase in diameter. In addition, it is desired that the first metal particle 106a on the first electrode layer 104a and the second metal particle 106b on the second electrode layer 104b have widths from one end to the other end of 20 nm or less, preferably 15 nm or less, more preferably 10 nm or less in planar view. The widths of the first metal particle 106a and the second metal particle 106b mean the maximum widths of isolated metal particles observed on the surfaces of the first electrode layer 104a and the second electrode layer 104b, respectively.

In the nanogap electrode 100, the first metal layer 114a and the second metal layer 114b are formed of a first metal, and the first metal particle 106a and the second metal particle 106b are formed of a second metal. The combination of the first metal and the second metal may be appropriately selected, but it is preferable that the first metal and the second metal form a metal bond and/or an alloy. With such a combination, the first metal particle 106a and the second metal particle 106b can be provided on the surfaces of the first electrode layer 104a and the second electrode layer 104b, respectively, in a state isolated from other metal particles.

The first metal particle 106a and the second metal particle 106b may be solid solutions formed of a first metal and a second metal. Since the first metal particle 106a and the second metal particle 106b form a solid solution, the mechanical stability of the nanogap electrode 100 can be enhanced.

As a metal material for forming the nanogap electrode, gold (Au) is considered to be suitable from the viewpoints of conductivity, chemical stability, and ability to form a self-assembled monolayer on the surface. However, it is known that gold (Au) decreases its melting point as it becomes nanoscale, becomes unstable due to Rayleigh instability, and changes its shape. For example, it is known that gold (Au) cannot maintain its shape as individual particles when it becomes a nanoparticle having a diameter of 10 nm or less. On the other hand, thermal stability is required to apply nano-devices with nanogap electrodes to industry. For example, the nanogap electrode is required to have a heat resistance of about 400° C. in the manufacturing process of the semiconductor integrated circuit. Therefore, the nanogap electrode is required not only to precisely control the length of the gap (gap length), but also to have thermal stability.

Here, the surface energy of a metal surface with a nanoscale radius of curvature is proportional to the inverse of the radius of curvature. In the presence of shapes with different radii of curvature, the metal atoms tend to be spherical with a large radius of curvature, which diffuses to the surface and has a stable energy, due to the Rayleigh instability. The migration rate of surface self-diffusion is proportional to surface self-diffusion coefficient and inversely proportional to the inverse of temperature. The surface tension is proportional to the inverse of the radius of curvature. The smaller the radius of curvature, the more likely the surface self-diffusion of metal atoms occurs.

For example, on the surface of the titanium (Ti) film formed on the substrate, to deposit gold (Au) by electron beam evaporation, when trying to produce an electrode having a line width of 20 nm or less, the electrode shape is changed at room temperature by Rayleigh instability. The reason for this is considered to be that the surface self-diffusion coefficient of gold (Au) at room temperature is as high as about 10⁻¹³ cm²/sec (C. Alonso, C. Salvarezzo, J. M. Vara, and A. J. Arvia, “The Evaluation of Surface Diffusion Coefficients of Gold and Platinum Atoms at Electrochemical Interfaces from Combined STM-SEM Imaging and Electrochemical Techniques”, J. Electrochem. Soc. Vol. 137, No. 7, 2161 (1990)).

Therefore, the nanogap electrode 100 employs combinations in which surface self-diffusion coefficient of the first metal forming the first electrode layer 104a and the second electrode layer 104b is smaller than surface self-diffusion coefficient of the second metal forming the first metal particle 106a and the second metal particle 106b. In other words, when the first electrode layer 104a and the second electrode layer 104b are formed of the first metal and the first metal particle 106a and the second metal particle 106b are formed of the second metal, a combination is applied in which surface self-diffusion coefficient of the second metal on the surfaces where the first metal and the second metal are bonded to each other is smaller than surface self-diffusion coefficient of the second metal. By such a combination, surface self-diffusion of the second metal is suppressed, and the first metal particle 106a and the second metal particle 106b can be formed as independent particles having a hemispherical shape.

An example of a combination of the first metal and the second metal is to use platinum (Pt) as the first metal and gold (Au) as the second metal. Specifically, the first electrode layer 104a and the second electrode layer 104b are preferably formed of platinum (Pt), and the first metal particle 106a and the second metal particle 106b are preferably formed of gold (Au), as one embodiment.

That is, by combining gold (Au) having a surface self-diffusion coefficient of 10⁻¹³ cm²/sec and platinum (Pt) having a surface self-diffusion coefficient of about 10⁻¹⁸ cm²/sec at normal temperature, it is possible to eliminate the effect of the Rayleigh instability and obtain a structurally stable nanogap element 100. That is, by combining platinum (Pt) having a low surface self-diffusion coefficient with gold (Au) while using gold (Au) suitable as the electrode material, the surface self-diffusion of gold (Au) in the growing process can be suppressed, and the shape-stability of the gold nanoparticles can be greatly improved. Platinum (Pt) has a high melting point of 1768° C., is excellent in heat resistance, is hard, is also chemically stable, and has a property of high durability. In addition, since platinum (Pt) forms a metal bond with gold (Au), surface diffusion of gold (Au) is suppressed in the process of growing gold (Au) particles on the platinum (Pt) surface, and gold (Au) particles having a hemispherical surface can stably exist.

Since the surface self-diffusion coefficient of gold (Au) is 10⁻¹³ cm²/sec and that of platinum (Pt) is about 10⁻¹⁸ cm²/sec, the surface self-diffusion coefficient of gold (Au) is five orders of magnitude smaller than that of platinum, and due to the existence of an alloy of gold (Au) and platinum (Pt), the surface self-diffusion coefficient of gold (Au) atoms on a platinum (Pt) surface is smaller than that of gold (Au) atoms when platinum is replaced with gold. Therefore, it is expected that metal particles 106 transverse direction (in-plane) formed of gold (Au) are prevented from diffusing on the surfaces of the electrode layers 104 formed of platinum (Pt).

If transverse direction diffusivity of the second metal on the surfaces of the first electrode layer 104a and the second electrode layer 104b formed of the first metal is large, the metal particles formed of the second metal have a large particle diameter, and the particles are connected to each other. Such a situation results in a problem that the shape of the nanogap electrode affects the properties of the nano-device and the desired properties cannot be obtained.

On the other hand, as exemplified in the present embodiment, since the metal particles 106 formed of the second metal (gold (Au)) are prevented from diffusing transverse direction on the surfaces of the first electrode layer 104a and the second electrode layer 104b formed of the first metal (platinum (Pt)), the large particle diameter is suppressed and the particles become small hemispherical particles. For example, the first metal particles 106a and the second metal particles 106b formed of gold (Au) have widths of 20 nm or less, preferably 15 nm or less, more preferably 10 nm or less, from one end to the other end in planar view on the surfaces of the first electrode layer 104a and the second electrode layer 104b formed of platinum (Pt), and can stably retain their shapes. The first metal particles 106a and the second metal particles 106b preferably have a curvature radius of 12 nm or less.

FIG. 1A, FIG. 1B, and FIG. 10 show an embodiment in which such first metal particles 106a are disposed at one end of the first electrode layer 104a, and similarly, the second metal particles 106b are disposed at one end of the second electrode layer 104b. Since the first metal particle 106a and the second metal particle 106b have a width of 20 nm or less from one end to the other end in planar view, the capacitance can be increased when one or both of the third electrode 102c and the fourth electrode 102d functioning as a gate electrode are disposed adjacently to the nanogap electrode 100. When fabricating a single-electron transistor using such a nanogap electrode 100, it is possible to modulate the drain current by the gate bias.

In the present embodiment, platinum (Pt) is used as the first metal for forming the first electrode layer 104a and the second electrode layer 104b, and gold (Au) is used as the second metal for forming the first metal particles 106a and the second metal particles 106b, but the present invention is not limited thereto. Other metal materials may be used as long as the first metal and the second metal form alloys and satisfy surface self-diffusion coefficient relation as described above.

A platinum (Pt) layer which forming the first electrode layer 104a and the second electrode layer 104b is provided on insulating surface. In the first electrode layer 104a and the second electrode layer 104b, another metal layer may be provided between the platinum layer and the base surface. As shown in the FIG. 10, in order to improve the adhesion of the platinum (Pt) layer, a titanium (Ti) layer may be provided between the platinum (Pt) layer and the underlying surface. The layer for improving the adhesion of the platinum (Pt) layer is not limited to titanium (Ti), and a layer formed of another transition metal such as chromium (Cr) or tantalum (Ta) may be used.

In the nanogap electrode 100, it is preferable that the first metal particles 106a and the second metal particles 106b having a width of 20 nm or less from one end to the other end are arranged in pairs in the gap portion. If a plurality of metal particles are disposed at one end of each of the first electrode layer 104a and the second electrode layer 104b, the metal nanoparticles or the functional molecules disposed in the gap portion of the nanogap electrode 100 cannot be controlled properly. In addition, when one or both of the third electrode 102c and the fourth electrode 102d used as gate electrode are disposed, it becomes difficult to apply gate-bias to the metal nanoparticles or the functional molecules disposed in the gap portion of the nanogap electrode 100.

The FIG. 1B shows a rectangular first electrode layer 104a and a rectangular second electrode layer 104b having widths W1. In order to arrange one first metal particle 106a at one end of the first electrode layer 104a and one second metal particle 106b at one end of the second electrode layer 104b in the nanogap electrode 100, it is preferable that the width W1 of the first electrode layer 104a and the second electrode layer 104b be 20 nm or less, preferably 15 nm or less. By setting the widths of the first electrode layer 104a and the second electrode layer 104b in this numerical range, the number of metal particles formed at one end of each of the first electrode layer 104a and the second electrode layer 104b can be controlled to be one. If the widths of the first electrode layer 104a and the second electrode layer 104b are 20 nm or more, the probability that a plurality of metal particles 106 are juxtaposed at one end increases, so that the value of the width W1 is preferably 20 nm or less.

As shown in the FIG. 10, the first metal particle 106a and the second metal particle 106b are hemispherical in cross section and have curved surfaces. Therefore, since tip portion where the first metal particle 106a and the second metal particle 106b face each other floats away from the surface of the substrate 110, when voltages are applied to one or both of the third electrode 102c and the fourth electrode 104d, a strong electric field acts on the gap portion.

On the other hand, in the nano-device, when the presence of a plurality of single electron islands in the gap portion (in the gap) is allowed, a plurality of sets of metal particles paired with the gap portion of the nanogap electrode may be arranged.

As shown in the FIG. 2A, by preparing the width W2 of the first electrode layer 104a and the second electrode layer 104b to be larger than 20 nm, for example, to be about 40 nm or just 40 nm, preferably about 30 nm or just 30 nm, and preparing the film thickness to be 20 nm or less, preferably 15 nm or less, a plurality of metal particles corresponding to the plurality of first metal particles 106a and the plurality of second metal particles 106b can be arranged in the respective width directions of the first electrode layer 104a and the second electrode layer 104b. Further, as shown in the FIG. 2B, by preparing the film thickness T2 of the first electrode layer 104a and the second electrode layer 104b to a value larger than 20 nm, for example, to a value of about 40 nm or just 40 nm, preferably about 30 nm or just 30 nm, and preparing the widths to be 20 nm or less, preferably 15 nm or less, a plurality of metal particles corresponding to the first metal particles 106a and the second metal particles 106b can be arranged in the thickness directions of the first electrode layer 104a and the second electrode layer 104b. Further, although not illustrated, by preparing the width of the first electrode layer 104a and the second electrode layer 104b to W2 and preparing the film thickness to T2, a plurality of metal particles can be arranged in the width direction of the first electrode layer 104a and the second electrode layer 104b, and a plurality of metal particles can also be arranged in the thickness direction of the first electrode layer 104a and the second electrode layer 104b. In other words, by preparing the dimensions of the first electrode layer 104a and the second electrode layer 104b to be larger than the size of the metal particles generated by the electroless plating and forming the metal particles to have a dimension such that a plurality of metal particles can be juxtaposed, the number of the first metal particles 106a and the second metal particles 106b generated on the end portion can be controlled to be plural without directly controlling the nucleation position.

In the nanogap electrode, when the arrangement of a plurality of metal particles on end portion of each of the first electrode layer 104a and the second electrode layer 104b is permitted, the widths and the film thicknesses of the first electrode layer 104a and the second electrode layer 104b may be appropriately set. For example, the width of the first electrode layer 104a and the second electrode layer 104b may be W1 and the film thickness may be T2, the width may be W2 and the film thickness may be T1, the width may be W2 and the film thickness may be T2.

The shapes of the first electrode layer 104a and the second electrode layer 104b are not limited to rectangular shapes. For example, as shown in the FIG. 3A, the first electrode layer 104a and the second electrode layer 104b may have a shape in which a tip portion of rectangular patterns is rounded and chamfered. As shown in the FIG. 3B, the first electrode layer 104a and the second electrode layer 104b may have rectangular patterns with sharp tip portion. As shown in FIG. 3A and FIG. 3B, the largest widths of the first electrode layer 104a and the second electrode layer 104b may be larger than 20 nanometers. In any of the cases, the first electrode layer 104a and the second electrode layer 104b can arrange the first metal particles 106a and the second metal particles 106b on the respective tip portion of the first electrode layer 104a and the second electrode layer 104b, as long as region having a width of 20 nm or less, preferably a width of 15 nm or less, and a film thickness of 20 nm or less, preferably 15 nm or less, is contained in one end portion where the metal particles 106 are provided.

FIG. 4A and FIG. 4B are diagrams schematically showing the nanogap electrodes 100 according to the present embodiment using a perspective view. FIG. 4A shows a first electrode layer 104a, a second electrode layer 104b, a third electrode layer 104c, and a fourth electrode layer 104d disposed on a substrate 110 comprising insulating surface. One end of each of the first electrode layer 104a and the second electrode layer 104b faces each other and are disposed apart from each other. The third electrode layer 104c and the fourth electrode layer 104d are arranged so as to sandwich a gap between the first electrode layer 104a and the second electrode layer 104b. Among these electrode layers, at least the first electrode layer 104a and the second electrode layer 104b are formed of platinum (Pt) as described above, or are arranged so that the platinum (Pt) surface is exposed.

FIG. 4B shows an embodiment in which metal particles are disposed on surfaces of the first electrode layer 104a, the second electrode layer 104b, the third electrode layer 104c, and the fourth electrode layer 104d. When the electroless plating method is used, a plurality of metal particles can be formed on the surface of the electrode layer. The first electrode layer 104a and the second electrode layer 104b face each other, and a pair of metal particles are disposed at one end portion forming a gap portion. Specifically, the first metal particle 106a are disposed at one end of the first electrode layer 104a, and the second metal particle 106b are disposed at one end of the second electrode layer 104b. The first metal particle 106a and the second metal particle 106b are disposed so as to protrude into the gap between the first electrode layer 104a and the second electrode layer 104b, but are not contacted with each other and are disposed apart from each other by controlling the size of particle diameter so as not to exceed the length of the gap. In this manner, by arranging the first electrode layer 104a and the second electrode layer 104b with a spacing of 20 nm, preferably 15 nm, and controlling the radii of curvature of the first metal particle 106a and the second metal particle 106b arranged on end portion of the first electrode layer 104a and the second electrode layer 104b to be 12 nm or less, in other words, by setting the widths of the first metal particles 106a and the second metal particles 106b from one end to the other end to be 20 nm or less on the surface of the electrode layer 104 in planar view, the length of the gap (gap length) can be controlled to be 10 nm or less.

The first metal particles 106a and the second metal particles 106b as shown in the FIG. 4B can be produced by electroless plating, and the gap between the electrodes can be precisely controlled by the self-terminating function of electroless plating. By forming metal particles by electroless plating, a plurality of metal particles 106 are generated on the surfaces of the first electrode layer 104a and the second electrode layer 104b. However, the first metal particles 106a and the second metal particles 106b are not formed as a continuous coating due to the control of surface self-diffusion, the low nucleation frequency, and the self-terminating function of electroless plating, and the individual metal particles are disposed in a substantially isolated state. The first metal particle 106a and the second metal particle 106b on the surfaces of the first electrode layer 104a and the second electrode layer 104b, respectively, are arranged randomly as long as the position of nucleation is not controlled, but nucleation proceeds preferentially at one end portion of the first electrode layer 104a and the second electrode layer 104b formed with a width of 20 nm or less, preferably 15 nm or less, and the first metal particles 106a and the second metal particles 106b can be arranged reliably.

According to the present embodiment, the width from one end to the other end of the first metal particle 106a and the second metal particle 106b which spaced apart from each other can be set to 20 nm or less respectively, and the distance between them can be arrange to 10 nm or less in the gap portion of the nanogap electrode 100.

As shown in the FIG. 1A, the first electrode 102a may be connected to the first pad 108a, and the second electrode 102b may be connected to the second pad 108b. The first pad 108a and the second pad 108b are arbitrary and may be provided as appropriate.

1-2 Method of Manufacturing a Nanogap Electrode

1-2-1 Manufacturing Process

A method of manufacturing the nanogap electrode 100 will be described with reference to the drawings. FIG. 5A shows a step of forming a metal film. As a substrate for manufacturing the nanogap electrodes 100, it is preferable to have insulating surface, and in order to form fine patterns, it is desirable to have excellent flatness and low warpage. For example, as the substrate 110, a silicon wafer on which the first insulating layer 112 such as a silicon oxide film is formed can be suitably used. The first insulating layer 112 formed by thermal oxidation on the surface of the silicon wafer is dense, it is suitable for excellent uniformity of the film thickness. As the substrate 110, a ceramic substrate formed of an insulating oxide material such as quartz substrate, alkali-free glass substrate, alumina, zirconia, or the like can be used.

On the upper surface of the first insulating layer 112, a metal layer 114 is formed. FIG. 5A shows a step of manufacturing the first metal layer 114a and the second metal layer 114b as the metal layer 114. For example, the first metal layer 114a is formed of titanium (Ti), and the second metal layer 114b is formed of platinum (Pt). A portion serving as a matrix for attaching the metal particles is formed by the second metal layer 114b. The first metal layer 114a is not an indispensable structure, and is provided as appropriate in order to improve the adhesion of the second metal layer 114b to the underlying surface. The first metal layer 114a and the second metal layer 114b are manufactured by using a thin film manufacturing technique such as an electron-beam evaporation method, a sputtering method, or the like. As the first metal layer 114a, a titanium (Ti) film is formed to a thickness of 2 nm to 10 nm, for example, 5 nm, and as the second metal layer 114b, a platinum (Pt) film is formed to a thickness of 5 nm to 20 nm, for example, 10 nm.

FIG. 5B shows the step of patterning the first metal layer 114a and the second metal layer 114b to form a first electrode layer 104a and a second electrode layer 104b having nanoscale gaps. The patterning of the first metal layer 114a and the second metal layer 114b is performed using a photolithography technique or an electron-beam lithography technique. That is, a resist mask is formed and the first metal layer 114a and the second metal layer 114b are etched, whereby the first electrode layer 104a and the second electrode layer 104b are formed. Although not illustrated, a resist mask may be formed on the substrate 110 prior to the formation of the first metal layer 114a and the second metal layer 114b, and then the first metal layer 114a and the second metal layer 114b may be formed and the resist mask may be peeled off to lift off the first metal layer 114a and the second metal layer 114b, thereby forming the first electrode layer 104a and the second metal layer 114b. The spacing L1 between the first electrode layer 104a and the second electrode layer 104b is 20 nm or less, preferably 15 nm or less, for example, 7.5 nm. The first electrode layer 104a and the second electrode layer 104b are manufactured to have a width of 20 nm or less, preferably 15 nm or less, for example, 17 nm.

FIG. 5C shows a step of manufacturing the first metal particles 106a and the second metal particles 106b. The first metal particles 106a and the second metal particles 106b are preferably produced by an electroless plating method. As solutions and reducing agents used in the electroless gold plating method, cyanide compound (cyanide), which is a toxic material, is well known. However, in the present embodiment, electroless gold plating is performed using iodine tincture. In the electroless gold plating, as the electroless plating solution, those obtained by dissolving iodine tincture and gold foil, the reducing agent uses L (+)-ascorbic acid (C₆H₈O).

When the electroless plating is performed, the metal particles 106 grow on the surfaces of the first electrode layer 104a and the second electrode layer 104b. The first metal particle 106a and the second metal particle 106b may grow at any position on the surfaces of the first electrode layer 104a and the second electrode layer 104b. However, since one end of each of the first electrode layer 104a and the second electrode layer 104b is formed to have a width of 20 nm or less, nucleation is preferentially performed by end portion, and the metal particles 106 are reliably generated.

In the process of electroless plating, monovalent positive ions of ascorbic acid and gold exist on the surfaces of the first electrode layer 104a and the second electrode layer 104b, and ascorbic acid acts as a reducing agent, so that a state of electrons is formed. At this time, on the surfaces of the first electrode layer 104a and the second electrode layer 104b, gold ions are reduced to gold by the surface autocatalytic reaction, and are plated. As a result, as shown in the FIG. 5C, the first metal particle 106a and the second metal particle 106b grow on end portion of the first electrode layer 104a and the second electrode layer 104b, respectively. However, as the first metal particle 106a and the second metal particle 106b grow and become larger, the spacing of the two metal particles becomes narrower. Then, a Helmholtz layer (a layer of solvent, solute molecules, and solute ions adsorbed on the electrode surface) is formed between the first metal particle 106a and the second metal particle 106b, and a state in which gold ions cannot enter the gap is formed. Therefore, if the spacing between the first metal particles 106a and the second metal particles 106b becomes narrow, the plating does not proceed. That is, by using a diffusion-controlled reaction system, the self-terminating function can be operated to control the gap length.

The first metal particles 106a and the second metal particles 106b are formed in a hemispherical shape on the surfaces of the first electrode layer 104a and the second electrode layer 104b. The width from one end to the other end of the first metal particle 106a and the second metal particle 106b having a hemispherical surface is preferably 20 nm or less. The radius of curvature of the first metal particle 106a and the second metal particle 106b is preferably 12 nm or less. The width and the radius of curvature from one end to the other end of the first metal particle 106a and the second metal particle 106b can be controlled by the processing time of the electroless plating.

When platinum (Pt) is used as the first electrode layer 104a and the second electrode layer 104b, gold (Au) deposited by reduction on the platinum (Pt) surface is metallurgically bonded to platinum (Pt). As a result, gold (Au) is grown on the platinum (Pt) surface such that transverse direction is suppressed from diffusing and a spherical surface is formed on the platinum (Pt) surface.

As described above, by performing electroless gold plating on platinum (Pt) surfaces, which are not frequently used in the related art, as shown in the FIG. 5C, the nanogap electrodes 100 in which the first metal particles 106a and the second metal particles 106b are close to each other and arranged with a gap therebetween are manufactured. Since the first metal particles 106a and the first electrode layer 104a, and the second metal particles 106b and the second electrode layer 104b are substantially metal bond to each other with gold (Au) and platinum (Pt), the first metal particles 106a and the second metal particles 106b are stably disposed on the surfaces of the first electrode layer 104a and the second electrode layer 104b, respectively.

1-2-2 Principle of Electroless Plating

As the electroless plating solution used in the present embodiment, an iodine tincture solution (a solution in which 12 and KI²⁻ are dissolved in ethanol solvents) in which a gold foil is dissolved is used. When such an electroless plating solution is used, it is possible to perform autocatalytic type electroless gold plating using a chemical reaction by the saturation state of gold.

The principle of this electroless plating is as follows. Gold dissolved in iodine tincture becomes saturated and the following equilibrium occurs.

2Au+I₃⁻I⁻↔2[AuI₂]⁻ (1)

[AuI₂]⁻+I₃⁻↔[AuI₄]⁻+I⁻ (2)

The following equilibrium states exist in tincture of iodine solution.

2KI+I₂↔2K⁺+I₃⁻+I⁻ (3)

Equation (3) is an endothermic reaction, and the equilibrium tilts to the right by heating the solution. Then, iodine ions (I⁻, I₃⁻) are generated, and a tri-valued gold ion (Au³⁺) is generated from the responses of Equations (1) and (2). In this condition, by introducing L(+)-ascorbic acid (C₆H₈O) as a reducing agent, the ratio of I⁻ ions is increased by the reduction of Equation (3).

C₆H₈O₆+I₃⁻→C₆H₆O₆+3I⁻+2H⁺ (4)

When the electrode is immersed in the solution in this reaction, the reaction of Equation (1) and Equation (2) of chemical equilibrium is directed toward the reaction on the left side where gold is electroless plated.

Monovalent gold ions (Au⁺) are reduced to nuclei on the platinum-electrode surfaces. In addition, electroless gold plating of the autocatalytic type progresses on the gold surface as a nucleus. Since L(+)-ascorbic acid is supersaturated in this plate, I₃⁻ continues to be reduced to I⁻ and the process is suppressed.

As noted above, in plating baths, the two reactions of nucleation electroless gold plating by reduction of monovalent gold ions (Au⁺) on the platinum surface and electroless gold plating on gold (Au) nuclei occur competitively.

1-2-3 Molecular Ruler Electroless Plating

In the step of manufacturing the first metal particles 106a and the second metal particles 106b shown in the FIG. 5C, a molecular ruler electroless plating method may be applied. The molecular ruler plating method is an electroless plating method using a surfactant molecule as a protective group as a molecular ruler, and a nanogap electrode 100 can be similarly produced.

In the molecular ruler electroless plating method, an electroless plating solution containing a surfactant which serves a function of a molecular ruler is used in addition to an iodine tincture solution containing gold (Au) and a reducing agent. As the surfactant, for example, alkyltrimethylammonium bromide, alkyltrimethylammonium halide, alkyltrimethylammonium chloride, alkyltrimethylammonium iodide, dialkyldimethylammonium bromide, dialkyldimethylammonium chloride, dialkyldimethylammonium iodide, alkylbenzyldimethylammonium bromide, alkylbenzyldimethylammonium iodide, alkylbenzyl dimethylammonium iodide, alkylamine iodide, N-methyl amine, N-methyl-1-dialkylamine, N-methyl-1-dialkylamine, alkylphosphine, alkyl phosphine, and the like can be used.

The surfactant chemisorbs to the metal particles deposited during the process of electroless plating. The surfactant has an alkyl chain, and the alkyl chain fills the gaps between the first metal particles 106a and the second metal particles 106b with an interleaved fit, thereby self-terminating the electroless plating. In this electroless plating method, it is possible to control the length of the gap (gap length) by changing the length of the alkyl chain of the surfactant. That is, when the alkyl chain length is increased, the gap length of the nanogap electrode can be increased.

As described above, the nanogap electrode having at least a pair of metal particles in the gap portion can also be manufactured by a molecular ruler electroless plating method. By using the molecular ruler electroless plating method, the length of the gap of the nanogap electrode can be controlled by the alkyl chain length of the surfactant.

According to this embodiment, by using the electroless plating method, it is possible to precisely control the electrode spacing (gap) of the nanogap electrode. More specifically, by performing electroless gold plating on platinum (Pt) surfaces, a nanogap electrode having an electrode spacing (gap) of 10 nm or less can be manufactured. In addition, by dissolving non-toxic iodine tincture and gold foil as the electroless plating solution and using L(+)-ascorbic acid (C₆H₈O) as the reducing agent, nanogap electrodes can be produced in large quantities at one time at room temperature.

### Second Embodiment

This embodiment shows an example of a nano-device using the nanogap electrode shown in the first embodiment. A nano-device 200a shown in the present embodiment has an operation configuration as a single-current transistor.

2-1 First Structure of the Nano-Device

FIG. 6A shows plan view of the nano-device 200a, and FIG. 6B shows the cross-sectional structures corresponding to B1-B2 spaces. The nano-device 200a is disposed on the substrate 110 and includes a first insulating layer 112, a nanogap electrode 100 (a first electrode 102a and a second electrode 102b), and a third electrode 102c and a fourth electrode 102d disposed to adjoin a gap portion of the nanogap electrode 100. The first electrode 102a includes a first electrode layer 104a and a first metal particle 106a, and the second electrode 102b includes a second electrode layer 104b and a second metal particle 106b. In the present embodiment, the spacing between the first metal particles 106a and the second metal particles 106b is preferably 5 nm or less.

The nano-device 200a further includes a self-assembled monolayer (SAM) 118. The self-assembled monolayer 118 is provided so as to cover at least the first electrode 102a and the second electrode 102b. In other words, the self-assembled monolayer 118 is provided so as to cover at least the surface of the first metal particle 106a and the second metal particle 106b.

The self-assembled monolayer 118 includes a first functional group that chemically adsorbs to a metal atom forming the first metal particle 106a and the second metal particle 106b, and a second functional group that is bonded to the first functional group. The first functional group is either a thiol group, a dithiocarbamate group, or a xanthate group. The second functional group is one in which some or all of the hydrogen molecules of an alkane, an alkene, an alkane or an alkene are substituted with fluorine, an amino group, a nitro group or an amide group.

For example, the self-assembled monolayer 118 is formed of a monomolecular film in which an alkanethiol is self-assembled. The self-assembled monolayer 118 is water-repellent and acts to keep the surface stable. A small number of alkane dithiols are mixed in the alkanethiol of the self-assembled monolayer 118. Alkane dithiol is formed by placing a bonding group thiol containing sulfur (S) at both ends of an alkane chain and has a shape in which sulfur (S) is present at each position of an alkanethiol monomolecular film. In order to incorporate an alkane dithiol into an alkanethiol, an electrode coated with an alkanethiol self-assembled monolayer 118 is immersed in a solution of an alkane dithiol, and a part of the alkanethiol is replaced with an alkane dithiol.

The nano-device 200a includes the metal nanoparticle 116 in the gap between the first electrode 102a and the second electrode 102b. The metal nanoparticle 116 are particles having a diameter of several nanometers, and gold (Au), silver (Ag), copper (Cu), nickel (Ni), iron (Fe), cobalt (Co), ruthenium (Ru), rhodium (Rh), palladium (Pd), iridium (Ir), platinum (Pt), or the like is used. The metal nanoparticle 116 are adsorbed on a self-assembled monomolecular 118 mixed film formed by the reaction of a self-assembled monomolecular with an organic molecule. Molecules such as alkanethiols that bind to the straight chain portion of the molecules constituting the self-assembled monolayer 118 are bound to the periphery. The metal nanoparticle 116 introduced into the gap portion between the first electrode 102a and the second electrode 102b are chemically bonded to the sulfur (S) contained in the alkane dithiol of the self-assembled monolayer 118 and become a stable state.

The nano-device 200a is covered with a second insulating layer 120 provided to bury the self-assembled monolayer 118 and the metal nanoparticle 116. The second insulating layer 120 is used as a protective film of the nano-device 200a.

As the substrate 110, a silicon wafer, silica substrate, alumina substrate, zirconia substrate, alkali-free glass substrate, or the like is used. As the substrate 110, when a silicon wafer is used, in order to ensure the insulating properties of the surface forming the electrode 102, it is preferable that the first insulating layer 112 is provided. The first insulating layer 112 is formed of an inorganic insulating film such as a silicon oxide film, a silicon nitride film, a silicon oxynitride film, an aluminum oxide film, or a magnesium oxide film.

The first electrode 102a, the second electrode 102b, the third electrode 102c, and the fourth electrode 102d have the same structure as that shown in the first embodiment and are manufactured in the same manner.

The nano-device 200a operate as a single-electron transistor. That is, the first electrode 102a is the source electrode, the second electrode 102b is drain electrode, and the third electrode 102c and the fourth electrode 102d are gate electrode. In the nano-device 200a of the present embodiment, the same voltage is applied to the third electrode 102c and the fourth electrode 102d. One of the third electrode 102c and the fourth electrode 102d used as gate electrode may be omitted.

The metal nanoparticle 116 disposed in the gap between the first electrode 102a and the second electrode 102b function as single-electron islands (also referred to as “Coulomb islands”). The nano-device 200a develops electron flow between the first electrode 102a and the second electrode 102b due to a tunnel effect with Coulomb blockade phenomenon.

A second insulating layer 120 is provided between the third electrode 102c and the fourth electrode 102d functioning as a gate electrode and the metal nanoparticle 116. In other words, the third electrode 102c and the fourth electrode 102d are insulated from the metal nanoparticle 116. The third electrode 102c and the fourth electrode 102d function as a gate electrode, and can modulate a current flowing between the first electrode 102a and the second electrode 102b. The nano-device 200a, i.e., the current (drain current) due to the tunnel effect with Coulomb blockade phenomenon between the source and the drain, allows the drain current to be modulated by the voltage applied to the gate.

The nano-device 200a can replace the metal nanoparticle 116 with functional molecules. That is, functional molecules can be disposed in the gap between the first electrode 102a and the second electrode 102b. Examples of the functional molecule include a molecule having a π-conjugated system skeleton and an oligomer. Even if the metal nanoparticle 116 are replaced with functional molecules, operation of the nano-device 200a can be similarly performed.

2-2 Second Structure of the Nano-Device

FIG. 7A and FIG. 7B show other structures of the nano-device 200a. FIG. 7A shows plan view of the nano-device 200a, and FIG. 7B shows the cross-sectional structures corresponding to B3-B4 spaces. The configuration of the third electrode 102c and the fourth electrode 102d is different from that of the nano-device shown in FIG. 6A and FIG. 6B.

As shown in the FIG. 7A, the third electrode 102c and the fourth electrode 102d are arranged so as to overlap with the gap portion of the nanogap electrode 100. As shown in the FIG. 7B, the third electrode 102c is disposed on the upper layer side of the second insulating layer 120, and the fourth electrode 102d is disposed on the lower layer side of insulating layer 104. As described above, in the nano-device 200a shown in FIG. 2A and FIG. 2B, the third electrode 102c and the fourth electrode 102d do not lie in the same plane as the nano gap electrode 100, but are arranged on the upper side or the lower side of the different layers with insulating layer interposed therebetween.

In the nano-device 200a shown in FIG. 7A and FIG. 7B, the third electrode 102c and the fourth electrode 102d are used as a gate electrode. A spacing between the third electrode 102c, the first metal particles 106a, and the second metal particles 106b can be adjusted by the thickness of the first insulating layer 112, the first electrode layer 104a, and the second electrode layer 104b. A spacing between the fourth electrodes 102d and the first metal particle 106a and the second metal particle 106b can be adjusted by the thickness of the second insulating layer 120. For example, by reducing the thickness of the first insulating layer 112 and the second insulating layer 120, the third electrode 102c and the fourth electrode 102d can be brought close to the first metal particle 106a and the second metal particle 106b. The same is true by reducing the thickness of the first electrode layer 104a and the second electrode layer 104b. The first insulating layer 112 and the second insulating layer 120 are produced by vapor phase growth methods such as the plasma-CVD (Chemical Vapor Deposition) method, and the first electrode layer 104a and second electrode layer 104b are produced by the deposition method or the sputtering method, so they can be thin film.

In the nano-device 200a shown in FIG. 7A and FIG. 7B, the third electrode 102c and the fourth electrode 102d are used as a gate electrode. In this case, by setting the width of the first metal particle 106a and the second metal particle 106b from one end to the other end on the electrode layer 104 to 20 nm or less, the electric field generated by the gate voltage can act on the metal nanoparticle 116. In addition, by making the first insulating layer 112 and the second insulating layer 120 thin film, the third electrode 102c and the fourth electrode 102d can be brought close to the metal nanoparticle 116, and the nano-device 200a can be driven at low voltages.

Note that although both the third electrode 102c and the fourth electrode 102d are shown in FIG. 7A and FIG. 7B, the present embodiment is not limited to this, and only one (only the third electrode 102c or only the fourth electrode 102d) may be provided.

As described in this embodiment, by using the nanogap electrode shown in the first embodiment, as one of the nano-devices, it is possible to realize a single-electron transistor. Since the length of gap of the nanogap electrode (gap length) is precisely controlled by the self-terminating function of the electroless plating, it is possible to suppress the characteristic variation of the single-electron transistor. Furthermore, since the nanogap electrode is thermally stable, it is possible to increase the reliability of the single-electron element.

### Third Embodiment

This embodiment shows an example of a nano-device using the nanogap electrode shown in the first embodiment. A nano-device 200b shown in this embodiment has an operation configuration as a logical operation device.

FIG. 8A shows plan view of the nano-device 200b implemented by the nano-device, and FIG. 8B shows a cross-sectional structure corresponding between C1-C2. The nano-device 200b according to the present embodiment includes the nano gap electrode 100 (the first electrode 102a and the second electrode 102b), the metal nano particle 116 disposed in the gap of the nano gap electrode 100, and the third electrode 102c, the fourth electrode 102d, and the fifth electrode 122 for adjusting the charge of the metal nano particle 116. In the nano-device 200b, the first electrode 102a and the second electrode 102b are used as a source electrode and a drain electrode, and the third electrode 102c, the fourth electrode 102d, and the fifth electrode 122 are used as a gate electrode.

As in the second embodiment, the self-assembled monolayer 118 may be provided on the surfaces of the first metal particle 106a and the 2 metal particle 106b, and the metal nanoparticle 116 may be chemically bonded to the sulfur (S) contained in the alkane dithiol of the self-assembled monolayer 18 The metal nanoparticle 116 may be replaced with functional molecules as in the second embodiment.

Similar to the second embodiment, the self-assembled monolayer 118 may be provided on the surfaces of the first metal particle 106a and the second metal particle 106b, and the metal nanoparticles 116 may be chemically bonded to sulfur (S) contained in the alkanedithiol of the self-assembled monolayer 118. As shown in FIG. 8A, the fifth electrode 122 covers the gap portion of the nanogap electrode 100 and is disposed at a position overlapping the metal nanoparticle 116. Also, as shown in FIG. 8B, the fifth electrode 122 is disposed on the second insulating layer 120.

The nano-device 200b in the present embodiment has the same structure as the single-electron transistor. The nano-device 200b can modulate charges to single-electron islands formed with metal nanoparticle 116 with a gate-voltage applied to gate electrode. Thus, between the source-drain (nanogap electrode 100), a state in which a current flow, that two states of a state in which no current flows appear periodically, so-called Coulomb oscillation phenomenon is observed.

The nano-device 200b having three gate electrodes can be used as a logical operation element for operation of exclusive OR (XORs), exclusive not OR (XNOR) by utilizing such phenomena. That is, by applying a voltage corresponding to the logical values “0” and “1” to the three gate electrodes of the nano-device 200b, it is possible to obtain a logic output corresponding to the logic of the XOR or XNOR. The detail of operation of the nano-device 200b capable of performing such a logical operation is the same as that of the logical operation device disclosed in WO2014/142039.

The nano-device 200b according to the present embodiment, by using the nanogap electrode shown in the first embodiment, even when operation as a logical operation element, it is possible to improve the stability and reliability of operation. That is, the length of the gap of the nanogap electrode (gap length), since it is precisely controlled by the self-terminating function of the electroless plating, it is possible to suppress the characteristic variation of the logic operation element. Furthermore, since the nanogap electrode is thermally stable, it is possible to increase the reliability of the logic operation element.

### Fourth Embodiment

This embodiment shows an example of a nano-device using the nanogap electrode shown in the first embodiment. A nano-device 200c shown in this embodiment mode has hysteresis in current-voltage characteristics and functions as a memory element.

FIG. 9A shows plan view of the nano-device 200c, and FIG. 9B shows the cross-sectional structures corresponding to D1-D2. The nano-device 200c includes a first insulating layer 112 provided on the substrate 110 and a nanogap electrode 100 (the first electrode 102a and the second electrode 102b) on the first insulating layer 112. The configuration of the nanogap electrode 100 is similar to that in the first embodiment. In the nano-device 200c, at least one halogen ion 124 is attached to one or both of the first metal particle 106a and the second metal particle 106b.

As the halogen ion 124, a bromine ion, a chlorine ion, an Iodine ion, or the like is applied. Halogen ion 124 are present in the gap of the nanogap electrode 100 and affect electrical conduction. The halogen ions 124 are not arranged in equal numbers on both the first electrode 102a and the second electrode 102b, but are arranged biased to one of the metal particles.

Halogen ions 124 change in valence when a voltage is applied to the nanogap electrode 100. As a result, a redox reaction occurs, or the number of halogen ions present in the gap changes. The number of halogen ions contributing to conduction changes, and the conductivity between the first electrode 102a and the second electrode 102b changes. As another interpretation, it is believed that the application of a voltage to the nanogap electrode 100 altered the conductivity due to the migration of the halogen ions 124. By such a phenomenon, the current-voltage characteristics of the nanogap electrode 100 will have a hysteresis.

Therefore, the nano-device 200c sets the writing voltage (Vwrite), reading voltage (Vread), and erasing voltage (Verase) as voltages to apply to the first electrode 102a, which is then operation as a memory element. The relationship between these three types of voltages is set so that the following relationship is satisfied.
(1) Write voltage (Vwrite)<0<Read voltage (Vread)<Erase voltage (Verase)
(2) Alternatively, write voltage (Vwrite)>0>read voltage (Vread)>erase voltage (Verase)

By setting operation voltages as described above, the nano-device 200c can realize three functions of writing, reading, and erasing as memory elements. Since the nano-device 200c can generate a high electric field in the gap even when the voltage applied to the nano gap electrode 100 is low, the valence of the halogen ion 124 can be easily changed. The nano-device 200c does not require a high voltage and can reduce power consumption.

Halogen ions 124, the electroless plating solution shown in the first embodiment, by performing electroless plating by mixing a surfactant containing halogen ions, it is possible to arrange the halogen ions 124 in the nanogap electrode 100.

In the present embodiment, by using the nanogap electrodes for realizing the memory element by the nano-device 200c, it is possible to improve the stability of operation, the low-voltage driving, and the reliability of the memory element. That is, the length of the gap of the nanogap electrode (gap length) is precisely controlled by the self-terminating function of the electroless plating, it is possible to suppress the characteristic variation of the memory element. Furthermore, since the nanogap electrode is thermally stable, the reliability of the memory element can be enhanced.

### Fifth Embodiment

This embodiment shows an example of a nano-device using the nanogap electrode shown in the first embodiment. A nano-device 200d shown in this embodiment mode has a floating gate and can be used as a memory element.

FIG. 10 shows a configuration of a nano-device 200d according to the present embodiment. The nano-device 200d has a structure similar to that of the nano-device 200a in the second embodiment. That is, the nano-device 200d includes the nano gap electrode 100 (the first electrode 102a and the second electrode 102b), the third electrode 102c, and the fourth electrode 102d. The nanogap electrode 100 includes a first metal particle 106a and a second metal particle 106b, and a self-assembled monolayer 118 is provided on at least the surface of the metal particle 106. The point where the metal nanoparticle 116 are disposed in the gap portion (gap) of the nanogap electrode 100 is also the same as in the second embodiment.

The nano-device 200d is configured such that the fourth electrodes 102d are used as a gate electrode and a gate voltage Vg is applied to the gate voltage Vg. The third electrode 102c is used as a floating gate electrode, and is configured to be applied with a floating voltage Vf via the switch 126. In the nanogap electrode 100, a first electrode 102a is used as a source electrode, and an ammeter is connected thereto. The second electrode 102b is used as a drain electrode, and is configured so that the drain voltage Vd is applied.

The nano-device 200d can store the states of charges of the metal nanoparticle 116 with charges stored in the third electrode 102c (corresponding to the floating gate electrode) even when the switch 126 is turned off after a current is passed between the first electrode 102a (corresponding to the source electrode) and the second electrode 102b (corresponding to drain electrode), and the floating voltage Vf is applied to the third electrode 102c (corresponding to the floating gate electrode). In addition, the charge state of the metal nanoparticle 116 can be changed stepwise by a voltage applied to the third electrode 102c, which corresponds to the floating gate electrode. As a result, the current flowing between the nanogap electrodes 100 can be stepwise varied. Therefore, by changing the floating gate voltage Vf in multiple stages, the charge state of the metal nanoparticle 116 are stepwise different, it is possible to use as a multi-valued memory.

Such an operation is similar to the nano-devices disclosed in WO2016/031836. However, since the nano-device 200d according to the present embodiment has the nano gap electrode 100 shown in the first embodiment, variations in element characteristics can be suppressed, heat resistance can be excellent, and reliability can be enhanced.

### Sixth Embodiment

The present embodiment shows an integrated circuit in which the nano-device exemplified in the second to fifth embodiments and an electronic device such as a MOS transistor are formed.

FIG. 11 shows an embodiment of an integrated circuit 202 according to the present embodiment. The integrated circuit 202 is provided with an electronic device such as a transistor, a diode, or the like in semiconductor substrate 128, the electronic device is connected by wiring, a circuit having a predetermined function is formed. In FIG. 11, a MOS transistor 130 is shown as an example of an electronic device.

The MOS transistor 130 is buried in interlayer insulating film 132. Between the nano-device 200 and the MOS transistor 130, several layers of interlayer insulating film may be stacked to form a multilayer wiring. FIG. 11 shows a structure in which a first interlayer insulating film 132a and a second interlayer insulating film 132b is stacked from the MOS transistor 130. The second interlayer insulating film 132b serving as a base surface of the nano-device 200 corresponds to the first insulating layer 112 described in the first embodiment, and is preferably formed of inorganic insulating film. For example, the second interlayer insulating film 132b is preferably formed of an inorganic insulating film such as a silicon oxide film, a silicon nitride film, a silicon oxynitride film, an aluminum oxide film, or a magnesium oxide film. The upper surface of the second interlayer insulating film 132b is preferably planarized by chemical mechanical polishing or the like.

The nano-device 200 is provided on the second interlayer insulating film 132b. The nano-device 200 is electrically connected to the MOS transistor 130, for example, by wiring 134 passing through the second interlayer insulating film 132b.

The type of the nano-device 200 is appropriately selected according to the application. That is, the nano-device 200 can be applied to integrated circuit 202 with various structures depending on the application, such as the single-electron transistor shown in the second embodiment, the logical operation element shown in the third embodiment, the memory element shown in the fourth embodiment, and the memory element provided with the floating gate shown in the fifth embodiment. For example, by using the nano-device 200a according to the second embodiment, it is possible to realize an integrated circuit for operation with low power dissipation. In addition, a memory cell can be formed using the nano-device 200c of the fourth embodiment and the nano-device 200d of the fifth embodiment.

The nano-device 200 is further buried in a second insulating layer 120. The upper layer of the second insulating layer 120, further multilayered wiring, bumps or the like may be formed. As described in the first embodiment, the nanogap electrodes 100 that make up the nano-devices 200 can be incorporated into the process of the semiconductor integrated circuit because they are highly heat resistant. For example, the fabrication of the nanogap electrode as described in the first embodiment can be performed in a metallization process.

As shown in this embodiment, the nano-device can be used as one of the elements constituting the semiconductor integrated circuit.

### Example 1

Example 1 shows an example of fabrication of a nanogap electrode. Fabrication step of the nanogap electrode has a step of producing a platinum electrode serving as a base of the electrode, and a step of applying an electroless gold plating on the surface of the platinum electrode.

1 Fabrication of Platinum (Pt) Electrodes

This example 1 shows an example in which the first electrode 102a and the second electrode 102b are formed using platinum. In this example 1, the first to fourth electrodes are referred to as platinum electrodes.

As a substrate for manufacturing platinum electrodes, a silicon wafer having a silicon oxide film formed on its surfaces was used. The substrate was cleaned by ultrasonic cleaning using acetone, ethanol, ultraviolet (UV) ozonation, or the like to form a clean surface.

An electron-beam resist solution (a resist solution obtained by mixing ZEP-520A (Nippon Zeon Corporation) and ZEP-A (Nippon Zeon Corporation)) was applied to the surface of substrate (the surface of the silicon oxide film) by a spinner to form a resist film, and then a prebake was performed. The substrate on which the resist film was formed was set in an electron-beam lithography device (ELS-7500EX manufactured by ELIONIX), and electron-beam lithography was performed on the resist film to form a resist film on which patterns for forming electrodes were formed. After that, development treatment was performed to form a resist pattern in which the drawn portions (portions corresponding to the electrode patterns) were in opening with each other.

Next, a titanium (Ti) film was formed on the patterned resist film using an electron-beam evaporation device (E-400EBS manufactured by Shimadzu Corporation), and a platinum (Pt) film was further formed on the patterned resist film. The titanium (Ti) film was formed to improve the adhesion of the platinum (Pt) film. A thickness of the titanium (Ti) film was 3 nm, and the thickness of the platinum (Pt) film was 10 nm.

The patterned resist film was peeled off by bubbling substrate on which the titanium (Ti) film and the platinum (Pt) film were laminated, immersed in a peeling solution (ZDMAC (manufactured by Zeon Corporation)) and allowed to stand. The metal layer in which the titanium (Ti) film and the platinum (Pt) film were laminated was lifted off together with peeling of the resist film. As a result, metallic layers remained in portions of opening patterns of the resist film, and other portions were peeled off and removed together with the resist film. In this way, a platinum electrode (more precisely, an electrode with a stack of titanium/platinum) was fabricated on the substrate.

Then, the fabrication of contact pads for electrical characteristics measurement was carried out. After the substrate on which the platinum electrodes were formed was cleaned, a positive resist was applied and prebaked to form a resist film. The resist film was exposed by a mask aligner (MA-20 manufactured by Mikasa Corporation) and developed to form a resist film having opening patterns corresponding to the pads for probe contacts.

Using an electron-beam evaporation apparatus (Shimadzu Corporation E-400EBS), titanium (Ti) film and platinum (Pt) film is laminated to form a metallic layer. Thereafter, the resist film was peeled off and the metal layer was lifted off to form a pad for probe contact.

The platinum (Pt) electrode thus prepared was observed with a scanning electron microscope (SEM), and the results are shown in FIG. 12A. From the SEM image, it was confirmed that the platinum electrode in which the length of the gap (gap length) was nano scale was formed.

2 Formation of Metal Particles

Metal particles were formed on a platinum (Pt) electrode. Gold (Au) was used as the material of the metal particles. The gold (Au) particles were formed on the platinum (Pt) electrode by an electroless plating method. Details of the manufacturing procedure of the nanogap electrode by the iodine electroless gold plating method on the platinum (Pt) electrode are shown below.

2-1 Preparation of Electroless Plating Solution

An electroless plating solution was produced. A 99.99% pure gold (Au) foil was placed in a container, and iodine tincture was added and stirred, followed by standing. In addition, L(+)-ascorbic acid (C₆H₈O) was added, and the mixture was allowed to stand after being heated. The solution allowed to stand was separated in a centrifuge. The supernatant of the solution after centrifugation was collected, heated in addition to another container containing L(+)-ascorbic acid (C₆H₈O), and agitated. Thereafter, an iodine tincture solution containing gold (Au) used for electroless plating was prepared by standing.

2-2 Electroless Plating

Before the electroless gold plating was performed, the platinum electrode was cleaned. Washing was carried out by acetone and ethanol. After cleaning, the surface was dried with nitrogen blow, and the organic matter on the surface was removed by UV-ozone treatment.

A pretreatment of the electroless gold plating was carried out. As the pretreatment of platinum (Pt) electrodes, the surface was treated with acid.

An iodine tincture solution containing ultrapure water and gold (Au) was placed in the plating bath to adjust the density of the electroless plating solution. To the plating bath, 8 mL of ultrapure water was added to 8 μL of an iodine tincture solution containing gold (Au). The platinum-electrode-formed substrate was immersed for 10 seconds. Substrate removed from the plating bath was rinsed with ultrapure water followed by sequential boiling with ethanol and acetone. Substrate was then dried by blowing.

The SEM image of the sample thus produced is shown in FIG. 12B. As is apparent from the SEM image, gold particles are observed to grow on the surface of the platinum (Pt) electrode.

Table 1 shows the results of evaluating the dimensions of the platinum electrode before and after the electroless plating by length measurement SEM. The length of the gap (gap length) of the platinum electrode was measured to be 17.8 nm, while the length of the gap (gap length) after electroless plating was measured to be 2 nm. In addition, the width of the platinum electrode changed from 17 nm to 20 nm. Further, the radius of curvature of the gold particles in the gap portion was observed to be 10 nm or less.

TABLE 1
Concentration of Plating Liquid: 8 μL/8 mL, Plating Time: 10 sec

| Pt Electrode Ti/Pt | Gap Length (nm) | Width (nm) |
|---|---|---|
| Pt Electrode | 17.8 | 17 |
| Electrode after plating | 2 | 20 |

Further, from the SEM image shown in FIG. 12B, it was observed that a plurality of gold particles attached on the platinum electrode were isolated one by one. It was observed that a pair of gold particles were formed in the gaps (tip portions) of the platinum electrodes, and gaps were formed between the platinum electrodes.

According to the results of the example 1, the platinum electrode, by applying an electroless gold plating, it was confirmed that it is possible to produce a nanogap electrode nanogap is formed with gold particles.

### Example 2

This example 2 shows the treatment condition dependence of the electroless plating. As the conditions of the electroless plating, the concentration of the electroless plating solution and the treatment time were compared and evaluated.

Evaluation was carried out using an iodine tincture solution containing gold (Au) prepared in the first example and varying the concentration diluted with ultrapure water. The prepared electroless plating solution was evaluated at two levels: a condition in which 8 μL of the stock solution was diluted with 8 mL of ultrapure water (hereinafter referred to as “condition 1”) and a condition in which 10 μL of the stock solution was diluted with 8 mL of ultrapure water (hereinafter referred to as “condition 2”).

FIG. 13A, FIG. 13B, and FIG. 13C show the results of evaluating the concentration dependence of the electroless plating solution. FIG. 13A shows SEM images of the initial state of the platinum electrode, FIG. 13B shows SEM images of samples immersed in the electroless plating solution of the condition 1 for 10 seconds, and FIG. 13C shows SEM images of samples immersed in the electroless plating solution of the condition 2 for 10 seconds.

According to the SEM images shown in FIG. 13A, FIG. 13B, and FIG. 13C, it was confirmed that the higher the concentration of the electroless plating solution, the faster the growth rate of gold (Au) and the larger the gold particles tend to grow. When the electroless plating solution of the condition 1 was used, the formation of hemispherical gold particles was confirmed. Furthermore, in the case of the electroless plating solution of the condition 1, it was observed that the gap of the nanogap electrode is maintained, it was confirmed that the self-terminating function has occurred. In addition, a tendency was observed in which hemispherical metal particles preferentially generated at the edge portion of the platinum electrode. From this, it was inferred that the generation position of the gold particles can be controlled by devising the shape of the platinum electrode. On the other hand, when the electroless plating solution of the condition 2 was used, the gold particles grown by electroless plating tended to grow faster and particle diameter became larger.

Next, FIG. 14A, FIG. 14B, and FIG. 14C show the results when the processing time of the electroless plating was changed in the electroless plating solution of the condition 1. FIG. 14A shows an initial state of the platinum electrode, FIG. 14B shows SEM images of samples subjected to electroless plating for 10 seconds, and FIG. 14C shows SEM images of samples subjected to electroless plating for 20 seconds.

Compared to the case where the electroless plating treatment time shown in FIG. 14B is 10 seconds, it is observed that gold (Au) particles grow larger in the sample that was performed for 20 seconds. From this result, it was found that by performing electroless plating for 10 seconds, particles of gold (Au) do not grow large, nanogap electrode present in an isolated state is obtained.

Furthermore, from the comparison of FIG. 14B and FIG. 14C, it was confirmed that the nanogap is maintained even by increasing the processing time of the electroless plating, it was confirmed that the self-terminating function is working in the electroless plating.

When the electroless plating solution of the condition 1 is used, when one gold atom is reduced on the platinum surface and the nucleus grows, if the electroless plating time is set to 20 seconds, neighboring nuclei are connected and particle diameter of hemispherical gold particles becomes large. This suggests that at the platinum surface, the reduction of monovalent gold ions continues to proceed, and hemispherical gold particles are formed.

According to the results of this example, it has been shown that by adjusting the concentration of the electroless plating solution and the processing time of the electroless plating, it is possible to control the length (gap length) of the gap in accordance with the size of the nanoparticles or functional molecules introduced between the gaps of the nanogap electrodes while utilizing the self-terminating function.

### Example 3

This example 3 shows the results of evaluating the curing of the pretreatment before the electroless gold plating is performed on the platinum electrode. The conditions for manufacturing the platinum electrode are the same as those in the first embodiment.

The pretreatment was evaluated under three conditions: (1) without pretreatment, (2) treatment with solution A (HCl diluted with ultrapure water), and (3) treatment with solution B (HClO₄ diluted with ultrapure water).

FIG. 15A, FIG. 15B, and FIG. 15C are SEM images of a sample processed under each condition and show a state after electroless gold plating. In each sample, electroless gold plating is performed for 10 sec using 8 μL of plating solution diluted with 8 mL of ultrapure water. FIG. 15A shows the sample without pretreatment, FIG. 15B shows the sample treated with solution A, FIG. 15C shows the SEM image of the sample treated with solution B.

As shown in FIG. 15A, FIG. 15B, and FIG. 15C, different growth states of gold particles are shown depending on the presence or absence of pretreatment and the difference in pretreatment conditions. Relatively large sized gold particles of 10 nm to 40 nm were identified in the sample without pretreatment shown in FIG. 15A. In this condition, it was confirmed that the gold particles were clustered. The pretreatment with solution A shown in FIG. 15B showed a slower rate of electroless gold plating. When solution A was used, gold was observed to nucleate into a hemispherical shape on the platinum surface. Further, in the pretreatment using solution B shown in FIG. 15C, the growth of particles of uniform gold (Au) on the surface of platinum (Pt) was observed. In the pretreatment with solution B, it was observed that a film of uniform gold (Au) was formed in a shorter time compared with solution A.

According to this example 4, it was confirmed that the growth of Au was different depending on the presence or absence of the pretreatment and the difference in the pretreatment conditions before the electroless plating was performed on the platinum electrode. The pretreatment is considered to contribute to nucleation when gold particles grow, and it was confirmed that the gold particles can be grown in a dispersed state by delaying the speed of electroless plating.

### Example 4

This example 4 shows the results of evaluating the heat resistance of the nanogap electrode. The nanogap electrode produced in the first embodiment 200° C., subjected to heat treatment for 2 hours, the shape changes before and after the heat treatment was observed by SEM.

FIG. 16A shows an SEM image of the sample before heat treatment, and FIG. 16B shows an SEM image after heat treatment. The nanogap electrode partially grown gold particles by electroless gold plating on the platinum electrode, at 200° C., although a change is observed in the heat treatment for 2 hours, the gold particles in the gap portion is observed to exist in the same state as before the heat treatment. When the SEM image of FIG. 16A prior to the heat treatment and the SEM image of FIG. 16B after the heat treatment are compared in detail, the SEM image having no change in particle diameter of the gold particles and the SEM image having a change in particle diameter are present on the first electrode 102a and the second electrode 102b.

On the other hand, the gold particles on the first pad 108a and the second pad 108b, which are wider than the first electrode 102a and the second electrode 102b, are in a state in which the grains cannot be confirmed after the heat treatment. The gold particles on the first pad 108a and the second pad 108b are difficult to be disposed apart from each other, and the gold atoms are diffused to change the shape of the gold particles, so that the platinum electrode surface is covered with the gold particles. From this, it is clear that the electrode width influences the formation process of the gold particles.

The gold particles on the first electrode 102a and the second electrode 102b whose particle diameter is changed are contacted with the adjoining gold particles on the surface of the platinum electrode, and the gold atoms are self-diffused on the surface due to Rayleigh instability, and tend to have a spherical shape with stable radii of curvature. At this time, since one of the adjoining gold particles is incorporated into the other gold particle, disappearance of the gold particle and the gold particle having a large particle diameter is observed at the same time.

On the other hand, gold particles that do not touch each other and are spaced apart at the platinum-electrode surfaces do not change in particle diameter and remain structural. In particular, it is important that the gold particles in the gap portion exist in the same state as before the heat treatment, which suggests that the gold particles in the gap portion have a strong tendency to be disposed apart from each other.

In addition, the fact that the shape is not changed even by the heat treatment at 200° C. promotes solid solution of the gold particles with platinum of the platinum electrode, and solid solution strengthening can form solid solution particles that are stronger than the gold particles.

On the other hand, the platinum electrode, in the nanogap electrode was subjected to electroless gold plating in place of the gold electrode, it has been reported that the electrode structure is broken by heat treatment at 200° C. (V. M. Serdio, et al., Nanoscale, 4, (2012), p. 7161). From this, it was confirmed that the nanogap electrode produced in this example was thermally stable.

### Reference Example

A titanium (Ti)/platinum (Pt) nanogap electrode subjected to electroless gold plating (hereinafter referred to as Sample 1) and a titanium (Ti)/gold (Au) nanogap electrode (hereinafter referred to as Sample 2) were evaluated for heat resistance. Both Sample 1 and Sample 2 have a structure in which gold is uniformly formed on the electrode surface by electroless plating. The heat resistance test was carried out at 400° C., 2 hours.

FIG. 17A shows an SEM image of Sample 1 before heat treatment, and FIG. 17B shows an SEM image after heat treatment. From this result, it was confirmed that the structure was also maintained by heat treatment at 400° C. for 2 hours in Sample 1. FIG. 17C shows an SEM image of Sample 2 before heat treatment, and FIG. 17D shows an SEM image after heat treatment. In Sample 2, it was observed that the electrode disappeared by heat treatment at 400° C. for 2 hours. From this, for Sample 1, it was confirmed that the structure of Sample 2 is inferior in heat resistance.

Considering the above results, it is considered that the gold (Au) atom electroless plated on the platinum (Pt) forms a metal-metal bond with the platinum (Pt) atom, and the platinum (Pt)-gold (Au) bond has a higher bonding energy than the gold (Au)-gold (Au) bond, so that the shape of the nanogap electrode can be maintained.

Further, not only the gold-platinum interface is formed, but also gold and platinum are formed into an alloy, and the gold particles are solidified, whereby gold-platinum particles with solid solution strengthening are formed, and the heat resistance is higher than that of platinum upper gold particles, and a strong gap structure can be produced.

Furthermore, than the nanogap electrode gold (Au) is uniformly formed by electroless plating, the nanogap electrode gold particles are formed by dispersing, due to the presence of the platinum electrode surface, the gold-platinum bonding because the surface self-diffusion of gold is less likely to occur, the radius of curvature of the gold particles is small, it is considered that more structurally stable. That is, in order to obtain a strong gap structure, it is important that the gold particles are not in contact with each other on the adjacent gold particles and the platinum surface, but are spaced apart from each other. Therefore, in the active device such as a transistor for performing the switching operation, as in the present embodiment, it is considered that the nanogap electrode gold (Au) particles are dispersed on the platinum electrode is suitable.

### Example 5

As an example 5, a nanogap electrode was produced using a molecular ruler electroless plating method in the following manner.

The first electrode layer 104a and the second electrode layer 104b are formed. Next, an electroless plating solution was prepared. As a molecular ruler, 25 mmol of alkyl-trimethylammonium bromide is measured by 28 mL. To that, 50 mmol of aqueous solution gold chloride is weighed 120 μL. Acetic acid was added to 1 mL as acid, and 0.1 mol of L(+)-ascorbic acid serving as a reducing agent and 3.6 mL were added, and the mixture was stirred well to obtain a plating solution.

In the example 5, molecular C12TAB was used as alkyl-trimethylammonium bromide.

Substrate with the first electrode 102a and the second electrode 102b prepared above was immersed in an electroless plating solution for about 3 minutes, 6 minutes, and 10 minutes. Thus, an electrode having a gap was produced by the molecular ruler electroless plating method of example 5.

FIG. 18A shows an SEM image obtained by manufacturing the first electrode 102a and the second electrode layer 102b using an EB lithography technique and performing molecular ruler electroless plating. When the molecular ruler electroless gold plating is performed for 3 minutes, a slightly hemispherical electroless gold plating grows. FIG. 18B is a case of performing molecular ruler electroless gold plating for 6 minutes, the molecular ruler electroless gold particles grow in the gap portion, the gap length is narrowed by the molecular ruler. FIG. 18C shows a case where the electroless gold plating of the molecular ruler is performed for 10 minutes, and the electrolytic plating of the molecular ruler proceeds to form a gold plating layer covering the surface of the platinum electrode. By the gap control mechanism by the molecular rule, a gap caused by the molecular length of the molecular rule is formed in the first electrode 102a and the second electrode layer 102b.

From the above, it has been shown that when the molecular ruler electroless gold plating method is used, it is possible to form the gap in which the gold particles face each other by hemispherical electroless gold plating, and it is possible to precisely control the gap length by the molecular ruler.

What is claimed is:

1. A nanogap electrode comprising:
a first electrode including a first electrode layer and a first metal particle arranged at a tip portion of the first electrode layer;
a second electrode including a second electrode layer and a second metal particle arranged at a tip portion of the second electrode layer;
the first metal particle and the second metal particle are arranged opposite to each other with a gap therebetween;
each of the first electrode layer and the second electrode layer has a uniform width of 20 nm or less to the tip portion and a film thickness of 20 nm or less;
a width from one end to the other end of the first metal particle and the second metal particle is 20 nm or less; and
the gap between the first metal particle and the second metal particle is 10 nm or less.

2. The nanogap electrode according to claim 1, wherein
the first electrode layer and the second electrode layer have an upper surface and a side surface and comprise a first metal,
the first metal particle and the second metal particle comprise a second metal different from the first metal, and
the first metal particle and the second metal particle are in contact with the upper surface and the side surface, respectively.

3. The nanogap electrode according to claim 2, wherein the first metal particle and the second metal particle have a hemispherical shape.

4. The nanogap electrode according to claim 3, wherein a radius of curvature of the first metal particle and the second metal particle are 12 nm or less.

5. The nanogap electrode according to claim 4, wherein the first metal particle is arranged to project from the tip portion of the first electrode layer, and the second metal particle is arranged to project from the tip portion of the second electrode layer.

6. The nanogap electrode according to claim 2, wherein the first metal particle and the second metal particle form a metal bond with the first electrode layer and the second electrode layer, respectively.

7. The nanogap electrode according to claim 1, wherein
a surface of the first electrode layer and the second electrode layer includes a plurality of metal particles other than the first metal particle and the second metal particle, and
the first metal particle, the second metal particle, and the plurality of metal particles are not in contact with each other on the surfaces of the first electrode layer and the second electrode layer, and are separated from each other.

8. The nanogap electrode according to claim 2, wherein the first metal is platinum, and the second metal is gold.

9. A method for manufacturing nano-gap electrode, the method comprising:
forming a first electrode layer and a second electrode layer each having a uniform width of 20 nm or less to the tip portion and a film thickness of 20 nm or less on a substrate having an insulating surface so that one ends of the first electrode layer and the second electrode layer are opposed to each other with a gap therebetween;
dipping the substrate on which the first electrode layer and the second electrode layer are formed in an electroless plating solution in which a reducing agent is mixed into an electrolyte containing metal ions,
forming metal particles one end of each of the first electrode layer and the second electrode layer; and
forming a metallic bond between a first metal forming the first electrode layer and the second electrode layer and a second metal different from the first metal contained in the electroless plating solution, growing the metal particles to a size in which the width from one end to the other end of the metal particles is not more than 10 nm, and forming a gap of 10 nm or less between the metal particles formed at the one end of the first electrode layer and the one end of the second electrode layer.

10. The method according to claim 9, wherein forming the metal particles in contact with a top and a side surfaces of the tip portions of the first electrode layer and the second electrode layer respectively.

11. The method according to claim 10, wherein forming the metal particles into a hemispherical shape.

12. The method according to claim 11, wherein forming a radius of curvature of the metal particles to 12 nm or less.

13. The method according to claim 9, wherein forming a metal bond between the first metal and the second metal at the interface where the first electrode layer and the first metal particle, and the second electrode layer and the second metal particle are in contact with each other.

14. The method according to claim 9, wherein forming a plurality of metal particles other than the first metal particle and the second metal particle on a surface of the first electrode layer and the second electrode layer.

15. The method according to claim 9, wherein forming the first electrode layer and the second electrode layer of platinum, and electroless plating the first electrode layer and the second electrode layer with an electroless plating solution containing gold ions.

16. The method according to claim 15, wherein forming the metal particles in a solid solution of platinum and gold.

17. The method according to claim 9, wherein the electroless plating solution contains L(+)-ascorbic acid, gold, and iodine tincture.

18. The method according to claim 9, wherein the electroless plating solution is diluted 800 times or more.

19. The method according to claim 9, further comprising treating surfaces of the first electrode layer and the second electrode layer with an acid, before dipping the substrate on which the first electrode layer and the second electrode layer with the electroless plating solution.
